(19) United States
(12) Patent Application Publication
(10) Pub. No.: US 2012/0145236 A1
(43) Pub. Date: Jun. 14, 2012

(54) UV-STABILIZED PHOTOVOLTAIC MODULE

(75) Inventor: Daisuke Fujiki, Tokyo (JP)

(73) Assignee: BASF SE, Ludwigshafen (DE)

(21) Appl. No.: 13/390,219

(22) PCT Filed: Aug. 12, 2010
(86) PCT No.: PCT/EP2010/061725

§ 371 Date: Mar. 1, 2012

(30) Foreign Application Priority Data
Aug. 18, 2009 (EP) 09168050.4

(51) Int. Cl. H01L 31/0216

(52) U.S. Cl. 136/256

(57) ABSTRACT

A photovoltaic module comprising the components: (1) a photovoltaic semiconductor and (2) one or more layers containing (A) independently of one another a synthetic polymer and (B) a mixture containing two or more different compounds selected from the group consisting of the compounds of the formulae (B-I) and (B-II); wherein E₁ is hydrogen, C₁-C₁₈alkyl, C₁-C₁₈alkyl substituted by 1, 2 or 3 radicals selected from the group consisting of —OH, C₂-C₁₈alkenyloxy, —C(O)OX₁ and —OC(O)X₂ with X₁ and X₂ being independently C₁-C₁₈alkyl; C₃-C₅₀alkyl interrupted by oxygen or C₃-C₅₀hydroxyalkyl interrupted by oxygen; E₂, E₃, E₄ and E₅ are independently hydrogen, C₁-C₁₈alkyl, phenyl or phenyl substituted by 1, 2 or 3 C₁-C₄alkyl; wherein A₀ is hydrogen or —OH; A₁, A₂, A₃ and A₄ are independently hydrogen, C₁-C₁₈alkyl, C₁-C₁₈alkyl substituted by 1, 2 or 3 radicals selected from the group consisting of —OH, C₂-C₁₈alkenyloxy, —C(O)OY₁ and —OC(O)Y₂ with Y₁ and Y₂ being independently C₁-C₁₈alkyl; C₃-C₅₀alkyl interrupted by oxygen or C₃-C₅₀hydroxyalkyl interrupted by oxygen; and optionally (C) at least one 2,2,6,6-tetramethylpiperidine derivative.

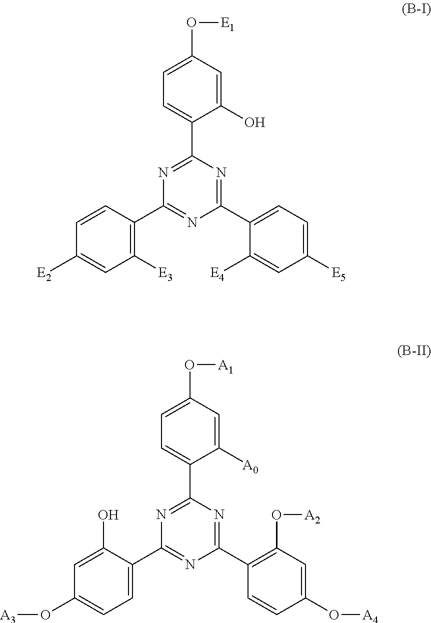

The present invention relates to a photovoltaic module comprising a photovoltaic semiconductor and at least one synthetic polymer layer containing two or more different hydroxyphenyltriazines and optionally a 2,2,6,6-tetramethylpiperidine derivative.

WO-A-2006/093,936 describes solar encapsulants with protective additives. Photovoltaic elements are disclosed in JP-A-2005-298,748.

EP-A-1,308,084 describes synergistic UV absorber combinations. Stabilizer compositions for polymers are disclosed in WO-A-2007/088,114 and GB-A-2,317,893.

Solar battery sealing material is described in EP-A-1,990,840.

UV stabilized solar cell XL-EVA encapsulants are described in IPCOM000139102D published Aug. 15, 2006.

The present invention relates in particular to a photovoltaic module comprising the components:

(1) a photovoltaic semiconductor and

(2) one or more layers containing
(A) independently of one another a synthetic polymer which is optionally crosslinked and
(B) a mixture containing two or more different compounds selected from the group consisting of the compounds of the formulae (B-I) and (B-II);

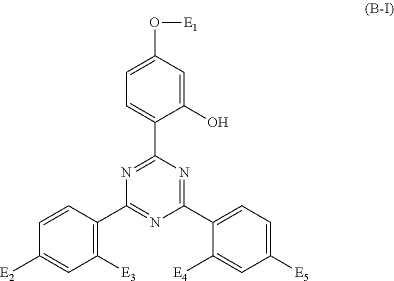

wherein E₁ is hydrogen, C₁-C₁₈alkyl, C₁-C₁₈alkyl substituted by 1, 2 or 3 radicals selected from the group consisting of —OH, C₂-C₁₈alkenyloxy, —C(O)OX₁ and —OC(O)X₂ with X₁ and X₂ being independently C₁-C₁₈alkyl; C₃-C₅₀alkyl interrupted by oxygen or C₃-C₅₀hydroxyalkyl interrupted by oxygen;
E₂, E₃, E₄ and E₅ are independently hydrogen, C₁-C₁₈alkyl, phenyl or phenyl substituted by 1, 2 or 3 C₁-C₄alkyl;

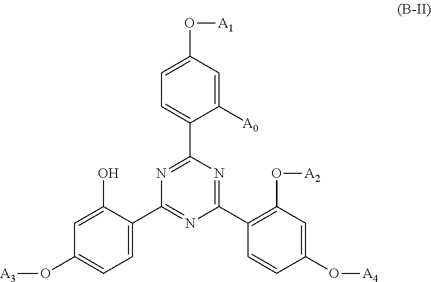

wherein A₀ is hydrogen or —OH;
A₁, A₂, A₃ and A₄ are independently hydrogen, C₁-C₁₈alkyl, C₁-C₁₈alkyl substituted by 1, 2 or 3 radicals selected from the group consisting of —OH, C₂-C₁₈alkenyloxy, —C(O)OY₁ and —OC(O)Y₂ with Y₁ and Y₂ being independently C₁-C₁₈alkyl; C₃-C₅₀alkyl interrupted by oxygen or C₃-C₅₀hydroxyalkyl interrupted by oxygen; and optionally
(C) at least one 2,2,6,6-tetramethylpiperidine derivative.

A photovoltaic module wherein component (A) is a crosslinked ethylene vinyl acetate copolymer and component (B) is a mixture containing a compound of the formula (B-I) and a compound of the formula (B-II) is particularly preferred.

Examples of C₁-C₁₈alkyl are methyl, ethyl, propyl, isopropyl, n-butyl, sec-butyl, isobutyl, tert-butyl, 2-ethylbutyl, n-pentyl, isopentyl, 1-methylpentyl, 1,3-dimethylbutyl, n-hexyl, 1-methylhexyl, n-heptyl, isoheptyl, 1,1,3,3-tetramethylbutyl, 1-methylheptyl, 3-methylheptyl, n-octyl, 2-ethylhexyl, 1,1,3-trimethylhexyl, 1,1,3,3-tetramethylpentyl, nonyl, decyl, undecyl, 1-methylundecyl, dodecyl, 1,1,3,3,5,5-hexamethylhexyl, tridecyl, tetradecyl, pentadecyl, hexadecyl, heptadecyl and octadecyl. C₁-C₈alkyl, for example methyl, n-butyl, 2-ethylhexyl or an isomeric mixture of octyl, is particularly preferred.

Preferred examples of C₁-C₁₈alkyl, preferably C₃-C₁₈ alkyl, substituted by 1, 2 or 3 radicals selected from the group consisting of —OH, C₂-C₁₈alkenyloxy, —C(O)OX₁ (or —C(O)OY₁) and —OC(O)X₂ (or —OC(O)Y₂) are 2-hydroxyethyl

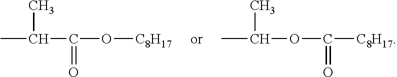

An example of C₃-C₅₀alkyl interrupted by one or more oxygen is —(CH₂CH₂—O—)₃—CH₃.

Preferred examples of C₃-C₅₀hydroxyalkyl interrupted by oxygen are

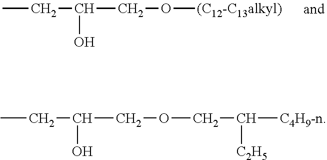

A preferred example of phenyl substituted by 1, 2 or 3 C₁-C₄alkyl is 2,4-dimethylphenyl.

Examples of a synthetic polymer are:

1. Polymers of monoolefins and diolefins, for example polypropylene, polyisobutylene, polybut-1-ene, poly-4-methylpent-1-ene, polyvinylcyclohexane, polyisoprene or polybutadiene, as well as polymers of cycloolefins, for instance of cyclopentene or norbornene, polyethylene (which optionally can be crosslinked), for example high density polyethylene (HDPE), high density and high molecular weight polyethylene (HDPE-HMW), high density and ultrahigh molecular weight polyethylene (HDPE-UHMW), medium density polyethylene (MDPE), low density polyethylene (LDPE), linear low density polyethylene (LLDPE), (VLDPE) and (ULDPE).

2. Mixtures of the polymers mentioned under 1), for example mixtures of polypropylene with polyisobutylene, polypropylene with polyethylene (for example PP/HDPE, PP/LDPE) and mixtures of different types of polyethylene (for example LDPE/HDPE).

3. Copolymers of monoolefins and diolefins with each other or with other vinyl monomers, for example ethylene/propylene copolymers, linear low density polyethylene (LLDPE) and mixtures thereof with low density polyethylene (LDPE), propylene/but-1-ene copolymers, propylene/isobutylene copolymers, ethylene/but-1-ene copolymers, ethylene/hexene copolymers, ethylene/methylpentene copolymers, ethylene/heptene copolymers, ethylene/octene copolymers, ethylene/vinylcyclohexane copolymers, ethylene/cycloolefin copolymers (e.g. ethylene/norbornene like COC), ethylene/1-olefins copolymers (which can optionally be crosslinked), where the 1-olefin is generated in-situ; propylene/butadiene copolymers, isobutylene/isoprene copolymers, ethylene/vinylcyclohexene copolymers, ethylene/alkyl acrylate copolymers, ethylene/alkyl methacrylate copolymers, ethylene/vinyl acetate copolymers or ethylene/acrylic acid copolymers and their salts (ionomers) as well as terpolymers of ethylene with propylene and a diene such as hexadiene, dicyclopentadiene or ethylidene-norbornene; and mixtures of such copolymers with one another and with polymers mentioned in 1) above, for example polypropylene/ethylene-propylene copolymers, LDPE/ethylene-vinyl acetate copolymers (EVA), LDPE/ethylene-acrylic acid copolymers (EAA), LLDPE/EVA, LLDPE/EAA and alternating or random polyalkylene/carbon monoxide copolymers and mixtures thereof with other polymers, for example polyamides.

4. Polymers derived from α,β-unsaturated acids and derivatives thereof such as polyacrylates and polymethacrylates; polymethyl methacrylates, polyacrylamides and polyacrylonitriles, impact-modified with butyl acrylate.

5. Polymers derived from unsaturated alcohols and amines or the acyl derivatives or acetals thereof, for example polyvinyl alcohol, polyvinyl acetate, polyvinyl stearate, polyvinyl benzoate, polyvinyl maleate, polyvinyl butyral, polyallyl phthalate or polyallyl melamine; as well as their copolymers with olefins mentioned in 1) above.

6. Polyphenylene oxides and sulfides, and mixtures of polyphenylene oxides with styrene polymers or polyamides.

7. Polyesters derived from dicarboxylic acids and diols and/or from hydroxycarboxylic acids or the corresponding lactones, for example polyethylene terephthalate, polybutylene terephthalate, poly-1,4-dimethylolcyclohexane terephthalate, polyalkylene naphthalate (PAN) and polyhydroxybenzoates, as well as block copolyether esters derived from hydroxyl-terminated polyethers; and also polyesters modified with polycarbonates or MBS.

8. Polycarbonates and polyester carbonates.

9. Polyurethane derived from hydroxy-terminated polyesters, polyesters or polybutadienes on the one hand and aliphatic or aromatic polyisocyanates on the other hand, as well as precursors thereof.

10. Polyamides and copolyamides derived from diamines and dicarboxylic acids and/or from aminocarboxylic acids or the corresponding lactams, for example polyamide 4, polyamide 6, polyamide 6/6, 6/10, 6/9, 6/12, 4/6, 12/12, polyamide 11, polyamide 12, aromatic polyamides starting from m-xylene diamine and adipic acid; polyamides prepared from hexamethylenediamine and isophthalic or/and terphthalic acid and with or without an elastomer as modifier, for example poly-2,4,4-trimethylhexamethylene terephthalamide or poly-m-phenylene isophthalamide; and also block copolymers of afore mentioned polyamides with polyolefins, olefin copolymers, ionomers or chemically bonded or grafted elastomers; or with polyethers, e.g. with polyethylene glycol, polypropylene glycol or polytetramethylene glycol; as well as polyamides or copolyamides modified with EPDM or ABS; and polyamides condensed during processing (RIM polyamide systems).

11. Blends of the aforementioned polymers (polyblends), for example PP/EPDM, Polyamide/EPDM or ABS, PVC/EVA, PVC/ABS, PVC/MBS, PC/ABS, PBTP/ABS, PC/ASA, PC/PBT, PVC/CPE, PVC/acrylates, POM/thermoplastic PUR, PC/thermoplastic PUR, POM/acrylate, POM/MBS, PPO/HIPS, PPO/PA 6.6 and copolymers, PA/HDPE, PA/PP, PA/PPO, PBT/PC/ABS or PBT/PET/PC.

12. Fluorinated polymers, for example poly(vinyl fluoride), fluorinated ethylene propylene copolymer resin, perfluoroalkoxy copolymer resin, poly(tetrafluoroethylene) or ethylene-tetrafluoroethylene copolymer.

13. Polysiloxanes, for example silicone such as alkyl substituted silicone (e.g. methyl silicone), partially vinyl-substituted silicone (VMQ, e.g. vinyl methyl silicone), partially phenyl substituted silicone (PMQ, e.g. phenyl methyl silicone), partially vinyl and phenyl substituted silicone (PVMQ, e.g. phenyl vinyl methyl silicone), partially fluoroalkyl substituted silicone (FMQ, e.g. 3,3,3-trifluoropropyl methyl silicone), partially fluoroalkyl vinyl substituted silicone (FVMQ, e.g. 3,3,3-trifluoropropyl vinyl methyl silicone), partially aminoalkyl substituted silicone (e.g. 3-aminopropyl methyl silicone), partially carboxyalkyl substituted silicone (e.g. 3-carboxypropyl methyl silicone), partially alkoxy substituted silicone (e.g. ethoxy methyl silicone), partially allyl substituted silicone (e.g. allyl methyl silicone) or silicone resins (highly crosslinked silicone).

Preferred synthetic polymers are those listed above under items 1, 3, 4, 7, 8, 9, 12 and 13.

The synthetic polymer is in particular selected from the group consisting of a linear or crosslinked polyolefin homopolymer, a linear or crosslinked polyolefin copolymer, a cyclic olefin homopolymer, a cyclic olefin copolymer, a poly(vinyl butyral), a crosslinked ethylene vinyl acetate copolymer, a polyester, a polycarbonate, a polyurethane, a fluorinated polymer, a poly(methyl methacrylate) and polysiloxane.

Typical photovoltaic modules contain, for example, the following layers:

Example I:

(a) Front Support Layer

(b) Encapsulant Layer
Crystalline silicon Layer

(b) Encapsulant Layer

(c) Back Substrate Layer

Example II:

(a) Front Support Layer
Transparent Conductor Layer
Amorphous Silicon Layer
Back Contact Layer

(b) Encapsulant Layer

(c) Back Substrate Layer

Example III:

(a) Front Support Layer

(b) Encapsulant Layer
Transparent Conductor Layer
Photovoltaic Semiconductor (containing e.g. up to 4 layers)
Back Contact Layer

(c) Back Substrate Layer

Example IV:

(a) Front Support Layer
Transparent Conductor Layer
Photovoltaic Semiconductor (containing e.g. 2 layers)
Transparent conductor Layer

(b) Encapsulant Layer

(c) Back Substrate Layer

According to a preferred embodiment of the present invention, the photovoltaic module contains as component (2) one or more layers selected from

(2-a) a front support layer,

(2-b) an encapsulating layer and

(2-c) a back substrate layer.

Layers (2-a), (2-b) and (2-c) are advantageously made of a synthetic polymer. If desired, layer (2-a) and/or (2-c) may alternatively be made of glass.

Further examples of preferred embodiments according to the present invention are listed below:

1. A photovoltaic module wherein the front support layer (2-a) contains a synthetic polymer (A) selected from a polyester, a poly(methyl methacrylate), a polycarbonate and a fluorinated polymer.

2. A photovoltaic module wherein the encapsulating layer (2-b) contains a synthetic polymer (A) selected from a linear or crosslinked polyolefin homopolymer, a linear or crosslinked polyolefin copolymer, a cyclic olefin homopolymer, a cyclic olefin copolymer, a poly(vinyl butyral), a crosslinked ethylene vinyl acetate copolymer, a polyurethane and a polysiloxane.

3. A photovoltaic module wherein the back substrate layer (2-c) contains a synthetic polymer (A) selected from a polyester, a polyamide and a fluorinated polymer.

The back substrate layer (2-c), itself, can also be a multilayers system of e.g. two or three layers. An example of a three layers system is:

(2-c-1) Fluorinated polymer layer

(2-c-2) Polyester layer

(2-c-3) Fluorinated polymer layer

The fluorinated polymer is preferably poly(vinylfluoride) or poly(ethylene tetrafluoroethylene).

A photovoltaic module wherein the photovoltaic semiconductor (1) contains a crystalline silicon or an amorphous silicon.

Preferred is further a photovoltaic module wherein two layers (the encapsulant layers) of component (2) contain as component (A) a crosslinked ethylene vinyl acetate copolymer, and component (B) as defined above.

Further preferred is the precursor of a photovoltaic module wherein two layers (the encapsulant layers) of component (2) contain as component (A) a linear ethylene vinyl acetate copolymer, and component (B) as defined above.

A suitable ethylene vinyl acetate copolymer has a relative weight content of vinyl acetate of 10 to 40%.

A further embodiment of the present invention is an encapsulant layer of a photovoltaic module containing components (A) and (B) as defined above. According to a preferred embodiment, the encapsulant layer contains as component (A) crosslinked ethylene vinyl acetate copolymer.

Another preferred embodiment of the present invention is the precursor of an encapsulant layer of a photovoltaic module containing as component (A) linear ethylene vinyl acetate copolymer, and component (B) as defined above. For the preparation of this precursor linear ethylene vinyl acetate copolymer is compounded with an organic compound having peroxide functionality, present component (B) and other ingredients and subsequently processed into a sheet without initiating crosslinking by the organic compounds having peroxide functionalities. In order to avoid crosslinking, the sheet processing temperature is lower than 120° C., preferably lower than 75° C.

The crosslinking process can be induced by addition of organic compounds with peroxide functionalities and exposure of the polymer to higher temperatures, since at higher temperatures the peroxide functionalities lead to the generation of reactive radicals. These radicals start said covalent bond formation reactions between different molecular chains of the synthetic polymer. The final degree of crosslinking of a certain synthetic polymer and also the crosslinking kinetics are dependent inter alia on the type and the amount of employed organic peroxide compounds, the process conditions like temperature and exposure time to a certain temperature. Furthermore, additives present in the synthetic polymer might influence the crosslinking process.

Examples for organic compounds with peroxide functionality are:

1. Hydroperoxides, for example tert-butylhydroperoxide or cumylhydroperoxide.

2. Alkyl/aryl peroxides, for example di-tert-butylperoxide, di-tert-amylperoxide, 2,2-bis-(tert-butylperoxy)butane, 2,5-dimethyl-2,5-di-(tert-butylperoxy)hexane, 2,5-dimethyl-3-hexyne-2,5-di-tert-butylperoxide, dicumylperoxide, bis-(1-tert-butylperoxy-1-methylethyl)-benzene, α,α′-bis-(tert-butylperoxy)diisopropylbenzene, 1,4-bis-(tert-butyl-peroxydiisopropyl)benzene or tert-butylcumylperoxide.

3. Peroxyesters, for example tert-butylperoxy benzoate, tert-butylperoxy 2-ethylhexanoate, tert-butyl-peroxy 3,5,5-trimethylhexanoate, didecanoyl peroxide, di-lauroyl peroxide or succinic acid peroxide.

4. Peroxycarbonates, for example peroxycarbonic acid O—O-tert-butyl ester O-isopropyl ester or peroxycarbonic acid O—O-tert-butyl ester O-(2-ethylhexyl) ester.

5. Diaroylperoxides, for example dibenzoylperoxide, di-(4-chlorobenzoyl)peroxide, di-(2,4-dichlorobenzoyl)peroxide or di-(4-methylbenzoyl)peroxide.

6. Peroxyketals, for example 1,1-di-tert-butylperoxy-3,5,5-trimethyl-cyclohexane, 1,1-di-(tert-amylperoxy)cyclohexane, ethyl 3,3-di-(tert-amylperoxy)butanoate or n-butyl 4,4-di-(tert-butylperoxy)valerate.

7. Cyclic peroxides, for example 3,6,9-triethyl-3,6,9-trimethyl-[1,2,4,5,7,8]hexoxonane or 3,3,6,6,9,9-hexamethyl-1,2,4,5-tetraoxocyclohexane.

Several organic peroxide compounds are commercially available, for example 2,5-dimethyl-2,5-di-(tert-butylperoxy)hexane contained in Luperox 101 (RTM Arkema Inc.) or peroxycarbonic acid O—O-tert-butyl ester O-isopropyl ester contained in Luperox TBEC (RTM Arkema Inc.).

The organic compound with peroxide functionality might be present in the synthetic polymer (A) prior to crosslinking in an amount of 0.001% to 10%, preferably 0.01% to 5% and particularly of 0.01% to 2% relative to the weight of the synthetic polymer (A).

Preferred is a photovoltaic module wherein an organic compound with peroxide functionality is present in component (A) prior to crosslinking in an amount of 0.001% to 10% relative to the weight of component (A).

Preferably, a crosslinking auxiliary can be added to improve the structure or level of crosslinking of the synthetic polymer. Furthermore, the crosslinking auxiliary can improve the gel content, the light stability and the heat stability of the crosslinked synthetic polymer.

Examples for crosslinking auxiliaries are triallylcyanurate, triallylisocyanurate and tri-methallylisocyanurate.

The crosslinking auxiliary can be added in a range of 0.1 to 10%, preferably 0.1 to 5% weight percent based on the weight of the synthetic polymer (A), which is to be crosslinked.

Preferred is a photovoltaic module wherein the layer or layers of component (2) are selected from a front support layer, an encapsulant layer and a back substrate layer.

The front support layer, the encapsulant layer and the back substrate layer are advantageously made of a synthetic polymer. If desired, the front support layer and/or the back substrate layer may alternatively be made for example out of glass or metal.

The photovoltaic modules can contain a photovoltaic semiconductor. Photovoltaic semiconductors contain typically for example crystalline silicon, armorphous silicon or—in case of composite semiconductors—CuInSe₂ (CIS), Cu(InGa)Se₂ (CIGS), Cu(InGa)(SSe)₂ or CdTe—CdS.

Preferred is a photovoltaic module wherein the photovoltaic semiconductor (1) contains crystalline silicon, amorphous silicon, CuInSe₂, Cu(InGa)Se₂ or CdTe—CdS.

The layer or layers of present component (2) are typically generated during the manufacturing process by converting sheets, which are made from a synthetic polymer (A) containing component (B) as defined above and optionally further additives. Said sheets can be prepared by conventional methods for plastic processing which are well known to those skilled in the art; for example solution casting methods, melt molding methods such as melt extrusion molding, press molding or injection molding, or the like. These methods may optionally contain additional processing steps such as orientation, lamination, co-extrusion or the like.

Present component (B), optional further additives and optional peroxides can be incorporated into the synthetic polymer prior or during the transformation into sheet or sheets. This or these sheets are afterwards converted during manufacturing of the photovoltaic module into the layer or layers of present component (2). These methods of incorporation are not particularly limited and well known to those skilled in the art. There may be mentioned, for example, the incorporation of the compounds of the formulae (B-I) and/or (B-II) into the synthetic polymer (A) or the use of a masterbatch comprising the compounds of the formulae (B-I) and/or (B-II) for the incorporation into the synthetic polymer. It is for example possible to supply the compounds of the formulae (B-I) and/or (B-II) during the melt extrusion molding and any of these methods may be employed.

If desired, the sheet or sheets as precursors of the layer or layers of present component (2) may be subjected to a treatment. A treatment is advantageous for improving the mutual adhesiveness of the sheets to other layers. Particularly, a surface treatment such as the application of a special coating by an adhesive to the sheet surface can improve the laminating process between sheets transforming into layers and layers, which remain mechanically rigid during the manufacturing process of the photovoltaic module. Here, mechanical rigidity refers to layers, which are not sensitive towards the warming applied during the manufacturing process of the photovoltaic module, for example layers out of glass, metal or polymers like specific polyesters.

Alternatively or in addition to a surface treatment of the sheet is the incorporation of an adhesion promoter into the synthetic polymer to improve the adhesiveness of the layer formed from the sheet during the manufacture of the photovoltaic module. Said adhesion promoter can be incorporated into the synthetic polymer similar to the methods mentioned for optional further additives and optional peroxides. The incorporation of the adhesion promoter can be performed simultaneously with optional further additives and optional peroxides, for example during a sheet formation out of poly(ethylene-co-vinylacetate).

Examples for adhesion promotors are silanes with a coupling functionality.

1. Vinylsilane, for example vinylchlorosilane, vinyl-tris-(2-methoxyethoxy)-silane, vinyl-triethoxy-silane, vinyl-triacetoxy-silane or vinyl-trimethoxy-silane.

2. Acryloxysilane, for example (3-(methacryloxy)propyl)-trimethoxy-silane.

3. Epoxysilane, for example (2-(7-oxa-bicyclo[4.1.0]hept-3-yl)ethyl)-trimethoxy-silane, (3-oxiranylmethoxy-propyl)-trimethoxy-silane or (3-oxiranylmethoxy-propyl)-diethoxy-methyl-silane.

4. Aminosilane, for example (N-(2-aminoethyl)-3-aminopropyl)-trimethoxy-silane, (N-(2-aminoethyl)-3-aminopropyl)-dimethoxy-methyl-silane, (3-aminopropyl)-triethoxy-silane or (N-phenyl-3-aminopropyl)-trimethoxy-silane.

5. Other types of silanes, for example (3-mercaptopropyl)-trimethoxy-silane or (3-chloropropyl)-trimethoxysilane.

Preferred as adhesion promoter is (3-(methacryloxy)propyl)-trimethoxy-silane.

Preferably, the amount of an adhesion promoter in a synthetic polymer (A) is from 0.01% to 5%, in particular from 1% to 4% relative to the weight of the synthetic polymer (A).

A standard manufacturing procedure for a photovoltaic module is exemplified for a module containing crystalline silicon, two layers of crosslinked poly(ethylene-co-vinylacetate), a front support layer out of glass and a back support layer out of polyester.

The standard structure of a photovoltaic module comprising cells which contain themselves photovoltaic semiconductors out of crystalline silicon is called superstrate structure. Such an element of superstrate structure is manufactured by arranging two-dimensionally several cells, which contain photovoltaic semiconductors and which are connected in tandem and in parallel.

A sheet out of ethylene vinyl acetate copolymer (=poly(ethylene-co-vinylacetate) as component (A) containing two different compounds of formulae (B-I) and/or (B-II) as component (B), an organic compound with peroxide functionality and optionally further additives, is placed on a sheet out of glass. This glass sheet will later be the front support layer of the finished photovoltaic module. On top of said sheet out of poly(ethylene-co-vinylacetate) is put the aforementioned arrangement of cells, which is followed by another sheet out of poly(ethylene-co-vinylacetate) containing two different compounds of formulae (B-I) and/or (B-II) as component (B), an organic compound with peroxide functionality and optionally further additives. Finally, a sheet out of polyester containing two different compounds of formulae (B-I) and/or (B-II) as component (B) and optionally further additives is placed on top. Said sheet out of polyester will later be the back support layer of the finished photovoltaic module.

The whole stack is now processed in a laminator, wherein as the first step a warming up to 180° C.; e.g. 150° C., takes place under vacuum and the temperature is maintained for 0.5 to 30 minutes, e.g. 10 minutes. During this period, the two sheets out of poly(ethylene-co-vinylacetate) melt by the heat (but not the polyester sheet as back support layer) and thereby encapsulate the cell arrangement and glue the glass and polyester sheets. In a second step, the whole stack is warmed further up to 180° C.; e.g. 150° C., in the laminator and kept at this temperature for 5 to 60 minutes, e.g. 20 minutes, in order to initiate and complete the crosslinking reaction of poly(ethylene-co-vinylacetate). Said crosslinking leads to improved mechanical properties in the layers formed now by the original sheets out of poly(ethylene-co-vinylacetate). After the cooling down of the stack, the photovoltaic module is completed by sealing of its edges, framing and installation of cables and a junction box.

With other photovoltaic module systems employing other photovoltaic semiconductors, such as a photovoltaic module containing amorphous silicon or a photovoltaic module containing a composite semiconductor, the cells may be generated by different ways, for example by spattering or chemical vapor deposition. However, the process of encapsulation is always similar, which means, the stack built from the sheets is processed in the laminator in order to melt the synthetic polymer foreseen as encapsulant, and initiate—if chosen—the crosslinking reaction afterwards.

Another embodiment of the present invention is a method for stabilizing a synthetic polymer in one or more layers being present in a photovoltaic module possessing a photovoltaic semiconductor, which comprises the addition of two different compounds of formulae (B-I) and/or (B-II) into the synthetic polymer.

A further preferred embodiment of the present invention is a photovoltaic module wherein component (B) is a mixture of a compound of the formula (B-I) and a compound of the formula (B-II).

The compound of the formula (B-I) is preferably a compound of the formula (B-I-a), (B-I-b), (B-1-c), (B-I-d), (B-I-e) or (B-I-f).

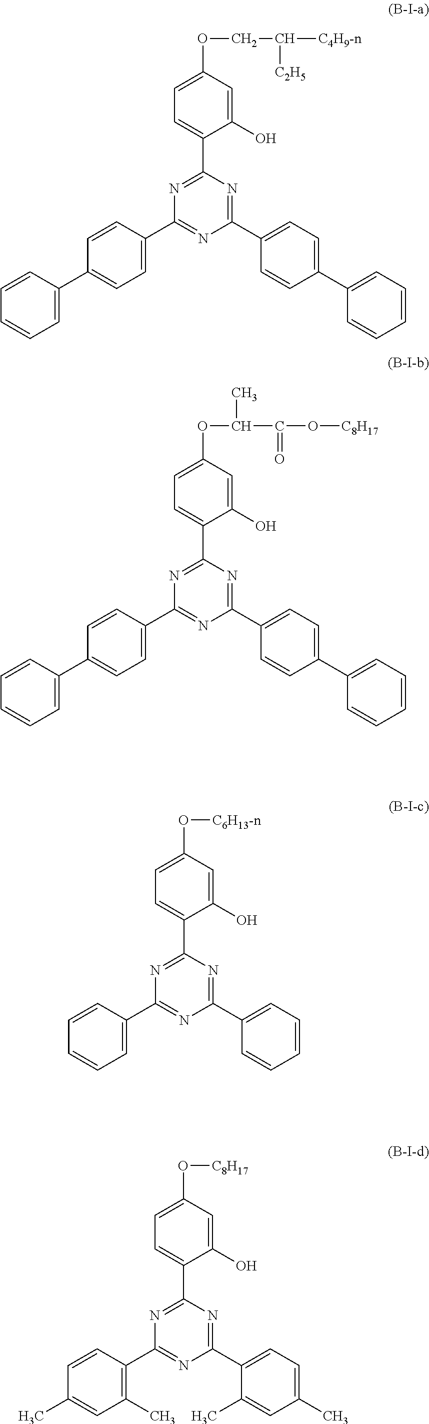

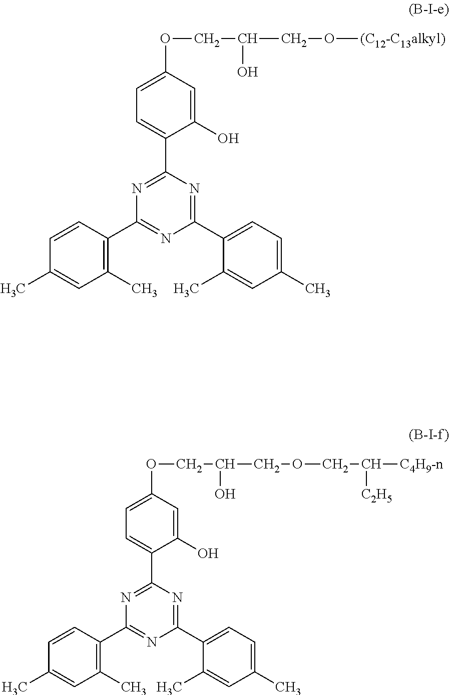

The compound of the formula (B-II) is preferably a compound of the formula (B-II-a), (B-II-b) or (B-II-c).

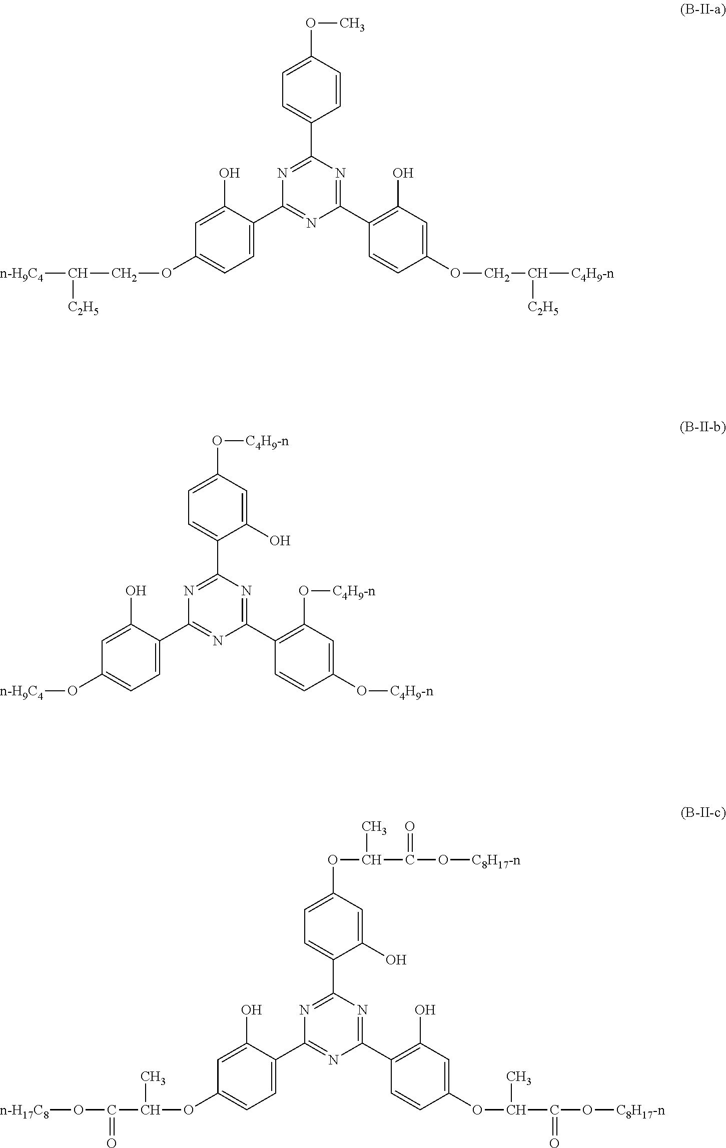

A particularly preferred embodiment of the present invention relates to a photovoltaic module wherein component (B) is

a mixture of the compounds (B-I-a) and (B-II-a),

a mixture of the compounds (B-I-a) and (B-II-b) or

a mixture of the compounds (B-I-c) and (B-II-c).

The compounds of the formulae (B-I) and (B-II) are essentially known and can be prepared in analogy to known methods, e.g. as described in U.S. Pat. No. 6,060,543. Some compounds are commercially available.

Examples of Component (C) are bis(2,2,6,6-tetramethyl-4-piperidyl)sebacate, bis(2,2,6,6-tetramethyl-4-piperidyl)succinate, bis(1,2,2,6,6-pentamethyl-4-piperidyl)sebacate, bis(1,2,2,6,6-pentamethyl-4-piperidyl) n-butyl-3,5-di-tert-butyl-4-hydroxybenzylmalonate, the condensate of 1-(2-hydroxyethyl)-2,2,6,6-tetramethyl-4-hydroxypiperidine and succinic acid, linear or cyclic condensates of N,N′-bis(2,2,6,6-tetramethyl-4-piperidyl)hexamethylenediamine and 4-tert-octylamino-2,6-dichloro-1,3,5-triazine, tris(2,2,6,6-tetramethyl-4-piperidyl)nitrilotriacetate, tetrakis(2,2,6,6-tetramethyl-4-piperidyl)-1,2,3,4-butanetetracarboxylate, 1,1′-(1,2-ethanediyl)-bis(3,3,5,5-tetramethylpiperazinone), 4-benzoyl-2,2,6,6-tetramethylpiperidine, 4-stearyloxy-2,2,6,6-tetramethylpiperidine, bis(1,2,2,6,6-pentamethylpiperidyl)-2-n-butyl-2-(2-hydroxy-3,5-di-tert-butylbenzyl)malonate, 3-n-octyl-7,7,9,9-tetramethyl-1,3,8-triazaspiro[4.5]decane-2,4-dione, linear or cyclic condensates of N,N′-bis(2,2,6,6-tetramethyl-4-piperidyl)hexamethylenediamine and 4-morpholino-2,6-dichloro-1,3,5-triazine, the condensate of 2-chloro-4,6-bis(4-n-butylamino-2,2,6,6-tetramethylpiperidyl)-1,3,5-triazine and 1,2-bis(3-aminopropylamino)ethane, the condensate of 2-chloro-4,6-di-(4-n-butylamino-1,2,2,6,6-pentamethylpiperidyl)-1,3,5-triazine and 1,2-bis(3-aminopropylamino)ethane, 8-acetyl-3-dodecyl-7,7,9,9-tetramethyl-1,3,8-triazaspiro[4.5]decane-2,4-dione, 3-dodecyl-1-(2,2,6,6-tetramethyl-4-piperidyl)pyrrolidine-2,5-dione, 3-dodecyl-1-(1,2,2,6,6-pentamethyl-4-piperidyl)pyrrolidine-2,5-dione, a mixture of 4-hexadecyloxy- and 4-stearyloxy-2,2,6,6-tetramethylpiperidine, a condensate of N,N′-bis(2,2,6,6-tetramethyl-4-piperidyl)hexamethylenediamine and 4-cyclohexylamino-2,6-dichloro-1,3,5-triazine, a condensate of 1,2-bis(3-aminopropylamino)ethane and 2,4,6-trichloro-1,3,5-triazine as well as 4-butylamino-2,2,6,6-tetramethylpiperidine (CAS Reg. No. [136504-96-6]); a condensate of 1,6-hexanediamine and 2,4,6-trichloro-1,3,5-triazine as well as N,N-dibutylamine and 4-butylamino-2,2,6,6-tetramethylpiperidine (CAS Reg. No. [192268-64-7]); N-(2,2,6,6-tetramethyl-4-piperidyl)-n-dodecylsuccinimide, N-(1,2,2,6,6-pentamethyl-4-piperidyl)-n-dodecylsuccinimide, 2-undecyl-7,7,9,9-tetramethyl-1-oxa-3,8-diaza-4-oxo-spiro-[4,5]decane, a reaction product of 7,7,9,9-tetramethyl-2-cycloundecyl-1-oxa-3,8-diaza-4-oxospiro-[4,5]decane and epichlorohydrin, 1,1-bis(1,2,2,6,6-pentamethyl-4-piperidyloxycarbonyl)-2-(4-methoxyphenyl)ethene, N,N′-bis-formyl-N,N′-bis(2,2,6,6-tetramethyl-4-piperidyl)hexamethylenediamine, a diester of 4-methoxymethylenemalonic acid with 1,2,2,6,6-pentamethyl-4-hydroxypiperidine, poly[methylpropyl-3-oxy-4-(2,2,6,6-tetramethyl-4-piperidyl)]siloxane, a reaction product of maleic acid anhydride-α-olefin copolymer with 2,2,6,6-tetramethyl-4-aminopiperidine or 1,2,2,6,6-pentamethyl-4-aminopiperidine, 1-(2-hydroxy-2-methylpropoxy)-4-octadecanoyloxy-2,2,6,6-tetramethylpiperidine, 5-(2-ethylhexanoyl)oxymethyl-3,3,5-trimethyl-2-morpholinone, Sanduvor (Clariant; CAS Reg. No. 106917-31-1], 5-(2-ethylhexanoyl)oxymethyl-3,3,5-trimethyl-2-morpholinone, 1,3,5-tris(N-cyclohexyl-N-(2,2,6,6-tetramethylpiperazine-3-one-4-yl)amino)-s-triazine, 1,3,5-tris(N-cyclohexyl-N-(1,2,2,6,6-pentamethylpiperazine-3-one-4-yl)amino)-s-triazine.

Component (C) is preferably a compound of the formula (C-I-a), (C-I-b), (C-I-c), (C-I-d) (C-II), (C-III) or (C-IV)

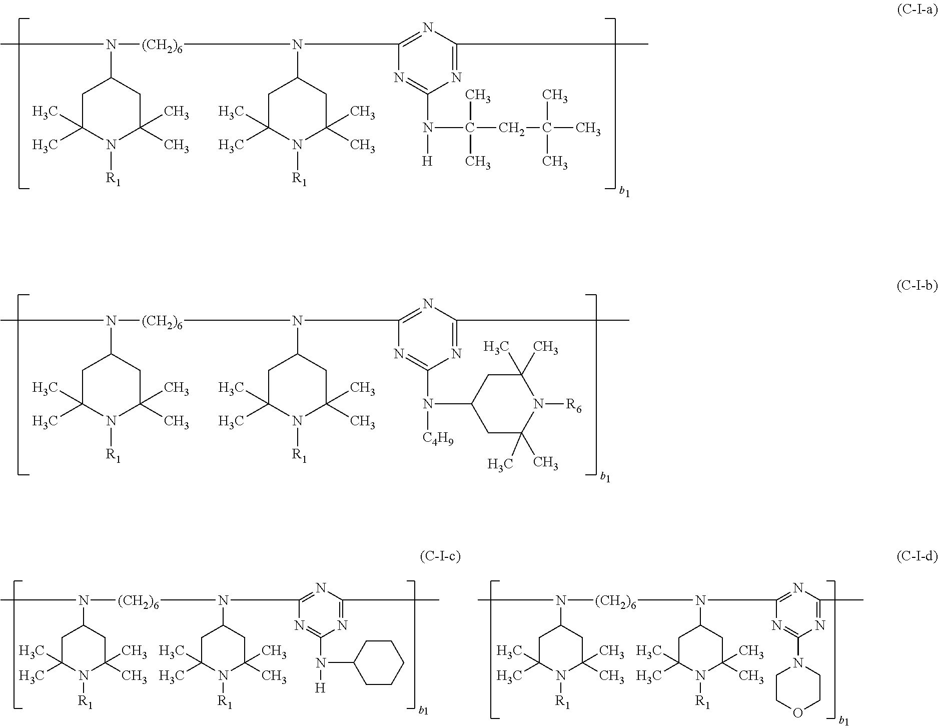

wherein b₁ is a number from 2 to 20, preferably 2 to 20, and the radicals R₁ are independently hydrogen, C₁-C₈alkyl, O, —OH, —CH₂CN, C₃-C₆alkenyl, C₇-C₉-phenylalkyl un-substituted or substituted on the phenyl by 1, 2 or 3 C₁-C₄alkyl; or C₁-C₈acyl;

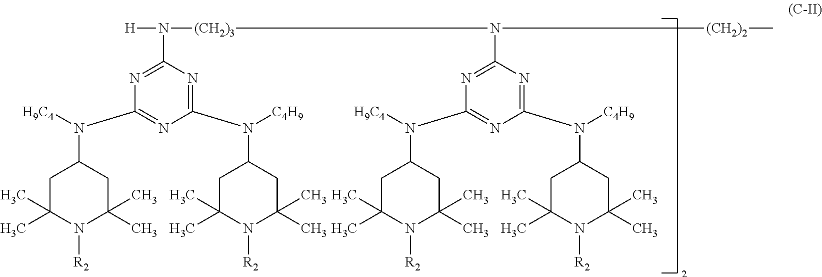

wherein the radicals R₂ have independently one of the meanings of R₁;

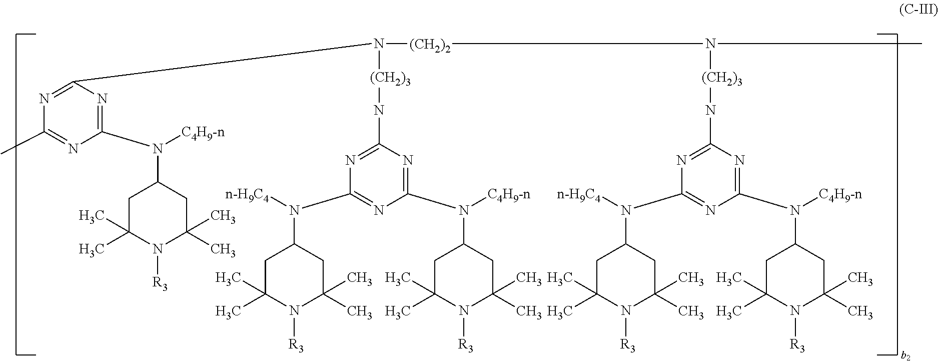

wherein b₂ is 2 to 20 and the radicals R₃ have independently one of the meanings of R₁;

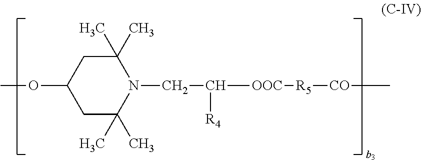

wherein R₄ is hydrogen or C₁-C₄alkyl,
R₅ is a direct bond or C₁-C₁₀alkylene, and
b₃ is a number from 2 to 20.

Examples of alkyl having up to 8 carbon atoms are methyl, ethyl, propyl, isopropyl, n-butyl, sec-butyl, isobutyl, tert-butyl, 2-ethylbutyl, n-pentyl, isopentyl, 1-methylpentyl, 1,3-dimethylbutyl, n-hexyl, 1-methylhexyl, n-heptyl, isoheptyl, 1,1,3,3-tetramethylbutyl, 1-methylheptyl, 3-methylheptyl, n-octyl, 2-ethylhexyl. C₁-C₄alkyl, in particular methyl, is preferred.

Examples of C₃-C₆alkenyl are allyl, 2-methallyl, butenyl, pentenyl and hexenyl. Allyl is preferred. The carbon atom in position 1 is preferably saturated.

Examples of C₇-C₉phenylalkyl unsubstituted or substituted on the phenyl by 1, 2 or 3 C₁-C₄alkyl are benzyl, phenylethyl, methyl benzyl, dimethylbenzyl, trimethylbenzyl and tert-butylbenzyl.

Examples of C₁-C₈acyl are formyl, acetyl, propionyl, butyryl, pentanoyl, hexanoyl, heptanoyl, octanoyl, acryloyl, methacryloyl and benzoyl. C₁-C₈Alkanoyl, C₃-C₈alkenyl and benzoyl are preferred. Acetyl and acryloyl are especially preferred.

Examples of C₁-C₁₀alkylene are methylene, ethylene, propylene, trimethylene, tetramethylene, pentamethylene, 2,2-dimethyltrimethylene, hexamethylene, trimethylhexamethylene, octamethylene and decamethylene.

R₁ is preferably hydrogen or methyl.

R₂ is preferably methyl.

R₃ and R₄ are preferably hydrogen.

R₅ is preferably ethylene.

The compounds of Component (C) are essentially known and can be prepared in analogy to known methods, as e.g. described in U.S. Pat. No. 4,086,204, U.S. Pat. No. 6,046,304, U.S. Pat. No. 4,331,586, U.S. Pat. No. 4,108,829, U.S. Pat. No. 4,477,615 and U.S. Pat. No. 4,233,412.

Preferred commercially available compounds of Component (C) are CHIMASSORB®944, CHIMASSORB®2020, DASTIB®1082, CYASORB®UV3346, CYASORB®UV3529, CHIMASSORB®119, UVASORB®HA 88 and TINUVIN®622.

The meanings of the terminal groups which saturate the free valences in the compounds of the formulae (C-I-a), (C-I-b), (C-I-c), (C-I-d), (C-II), (C-III) and (C-IV) depend on the processes used for their preparation. The terminal groups can also be modified after the preparation of the compounds.

If the compounds of the formula (C-I-a), (C-I-b), (C-I-c) or (C-I-d) are prepared by reacting a correspondingly substituted 2,5-dichlorotriazine with a diamine compound of the formula

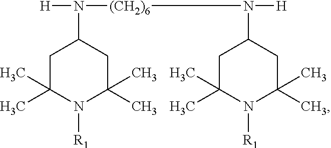

the terminal group bonded to the diamino radical is hydrogen or a correspondingly substituted triazinyl residue, e.g. in the case of the formula (C-1-a) the group

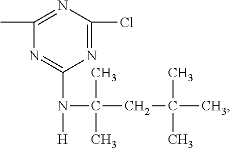

and the terminal group bonded to the triazine radical is Cl or the group

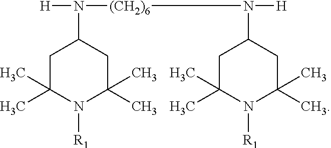

It may be advantageous to replace the —Cl, for example, by —OH or an amino group when the reaction is complete. Examples of amino groups which may be mentioned are pyrrolidin-1-yl, morpholino, —NH₂, —N(C₁-C₈alkyl)₂ and —NR(C₁-C₈alkyl), in which R is hydrogen or a 2,2,6,6-tetramethyl-4-piperidyl group.

In the compounds of the formula (III-c) the terminal group bonded to the triazine radical is, for example, Cl or a

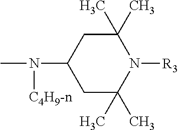

group, and the terminal group bonded to the amino radical is, for example, hydrogen or a

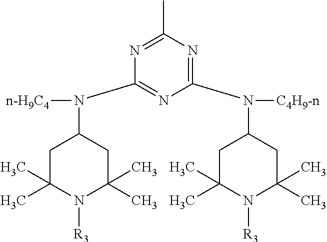

group.

If the compounds of the formula (C-IV) are prepared, for example, by reacting a compound of the formula

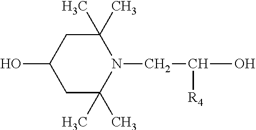

with a dicarboxylic acid diester of the formula Y₀—OOC—R₅—COO—Y₀, in which Y₀ is, for example, methyl, ethyl or propyl, the terminal group bonded to the 2,2,6,6-tetramethyl-4-oxypiperidin-1-yl radical is hydrogen or —CO—R₅—COO—Y₀, and the terminal group bonded to the diacyl radical is —O— Y₀ or

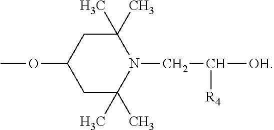

Particularly preferred compounds of Component (C) are

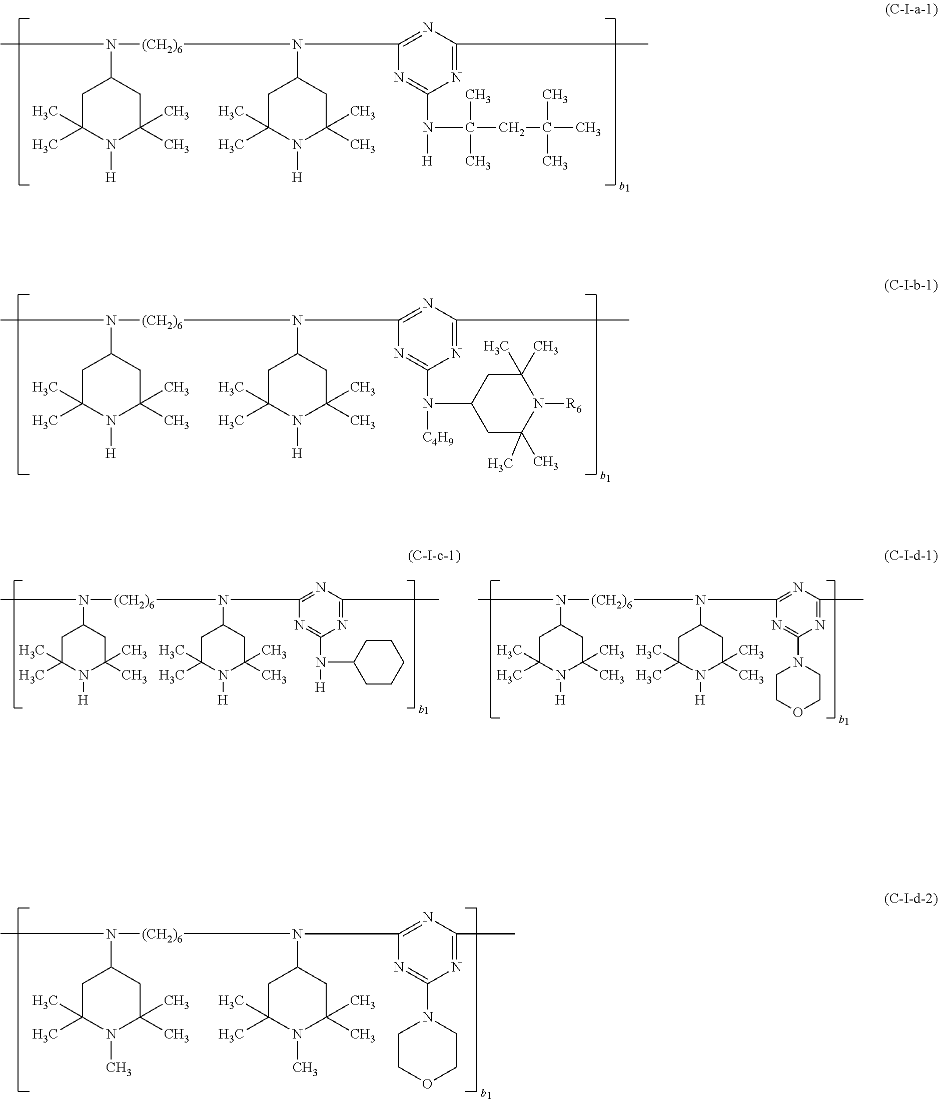

wherein b₁ is 2 to 20 in the formulae (C-I-a-1), (C-I-b-1), (C-I-c-1), (C-I-d-1) and (C-I-d-2),

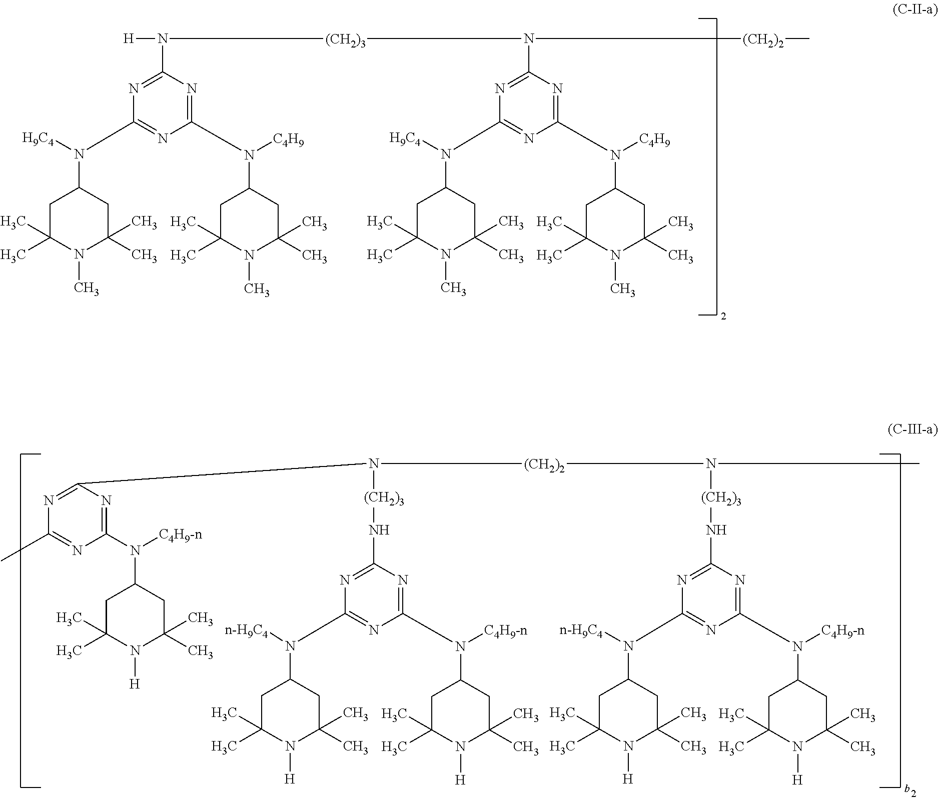

wherein b₂ is 2 to 20;

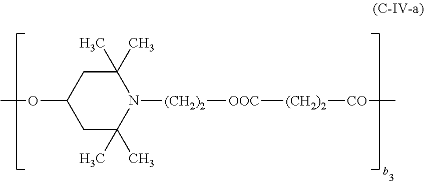

wherein b₃ is a number from 2 to 20.

One of the particularly preferred compounds of the formula (C-I-b) is

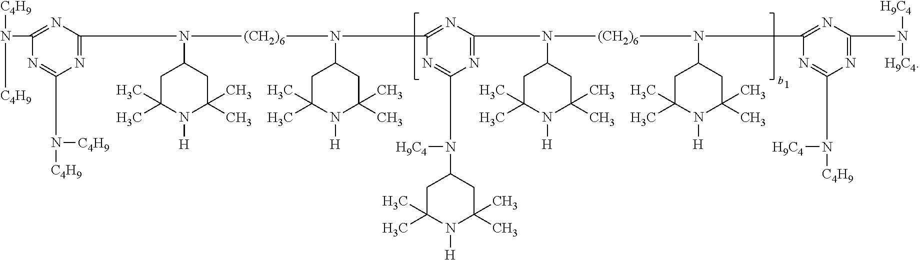

The preparation of this compound is described in Example 10 of U.S. Pat. No. 6,046,304.

A preferred embodiment of the present invention relates to a photovoltaic module wherein the layer or layers of component (2) contain the components (A), (B) and (C).

A further preferred embodiment of the present invention relates to a photovoltaic module wherein

component (A) is a synthetic polymer selected from a cyclic olefin polymer, a polycarbonate, a crosslinked ethylene vinyl acetate copolymer and a poly(methyl methacrylate);
component (B) is
a mixture of the compounds (B-I-a) and (B-II-a),
a mixture of the compounds (B-I-a) and (B-II-b) or
a mixture of the compounds (B-I-c) and (B-II-c); and
component (C) is a compound of the formula (C-II-a).

As already described above, if desired, the layer or layers of component (2) may further contain one or more conventional additives. Suitable examples are listed in the following.

### 1. Antioxidants

1.1. Alkylated monophenols, for example 2,6-di-tert-butyl-4-methylphenol, 2-tert-butyl-4,6-dimethylphenol, 2,6-di-tert-butyl-4-ethylphenol, 2,6-di-tert-butyl-4-n-butylphenol, 2,6-di-tert-butyl-4-isobutylphenol, 2,6-dicyclopentyl-4-methylphenol, 2-(α-methylcyclohexyl)-4,6-dimethylphenol, 2,6-dioctadecyl-4-methylphenol, 2,4,6-tricyclohexylphenol, 2,6-di-tert-butyl-4-methoxymethylphenol, nonylphenols which are linear or branched in the side chains, for example, 2,6-di-nonyl-4-methylphenol, 2,4-dimethyl-6-(1′-methylundec-1′-yl)phenol, 2,4-dimethyl-6-(1′-methylheptadec-1′-yl)phenol, 2,4-dimethyl-6-(1′-methyltridec-1′-yl)phenol and mixtures thereof.

1.2. Alkylthiomethylphenols, for example 2,4-dioctylthiomethyl-6-tert-butylphenol, 2,4-dioctylthiomethyl-6-methylphenol, 2,4-dioctylthiomethyl-6-ethylphenol, 2,6-di-dodecylthiomethyl-4-nonylphenol.

1.3. Hydroquinones and alkylated hydroquinones, for example 2,6-di-tert-butyl-4-methoxyphenol, 2,5-di-tert-butylhydroquinone, 2,5-di-tert-amylhydroquinone, 2,6-diphenyl-4-octadecyloxyphenol, 2,6-di-tert-butylhydroquinone, 2,5-di-tert-butyl-4-hydroxyanisole, 3,5-di-tert-butyl-4-hydroxyanisole, 3,5-di-tert-butyl-4-hydroxyphenyl stearate, bis(3,5-di-tert-butyl-4-hydroxyphenyl)adipate.

1.4. Tocopherols, for example α-tocopherol, β-tocopherol, γ-tocopherol, δ-tocopherol and mixtures thereof (vitamin E).

1.5. Hydroxylated thiodiphenyl ethers, for example 2, 2′-thiobis(6-tert-butyl-4-methylphenol), 2,2′-thiobis(4-octylphenol), 4,4′-thiobis(6-tert-butyl-3-methylphenol), 4,4′-thiobis(6-tert-butyl-2-methylphenol), 4,4′-thiobis(3,6-di-sec-amylphenol), 4,4′-bis(2,6-dimethyl-4-hydroxyphenyl)disulfide.

1.6. Alkylidenebisphenols, for example 2, 2′-methylenebis(6-tert-butyl-4-methylphenol), 2,2′-methylenebis(6-tert-butyl-4-ethylphenol), 2,2′-methylenebis[4-methyl-6-(α-methylcyclohexyl)phenol], 2,2′-methylenebis(4-methyl-6-cyclohexylphenol), 2,2′-methylenebis(6-nonyl-4-methylphenol), 2,2′-methylenebis(4,6-di-tert-butylphenol), 2,2′-ethylidenebis(4,6-di-tert-butylphenol), 2,2′-ethylidenebis(6-tert-butyl-4-isobutylphenol), 2,2′-methylenebis[6-(α-methylbenzyl)-4-nonylphenol], 2,2′-methylenebis[6-(α,α-dimethylbenzyl)-4-nonylphenol], 4,4′-methylenebis(2,6-di-tert-butylphenol), 4,4′-methylenebis(6-tert-butyl-2-methylphenol), 1,1-bis(5-tert-butyl-4-hydroxy-2-methylphenyl)butane, 2,6-bis(3-tert-butyl-5-methyl-2-hydroxybenzyl)-4-methylphenol, 1,1,3-tris(5-tert-butyl-4-hydroxy-2-methylphenyl)butane, 1,1-bis(5-tert-butyl-4-hydroxy-2-methyl-phenyl)-3-n-dodecylmercaptobutane, ethylene glycol bis[3,3-bis(3′-tert-butyl-4′-hydroxyphenyl)butyrate], bis(3-tert-butyl-4-hydroxy-5-methyl-phenyl)dicyclopentadiene, bis[2-(3′-tert-butyl-2′-hydroxy-5′-methylbenzyl)-6-tert-butyl-4-methylphenyl]terephthalate, 1,1-bis-(3,5-dimethyl-2-hydroxyphenyl)butane, 2,2-bis(3,5-di-tert-butyl-4-hydroxyphenyl)propane, 2,2-bis(5-tert-butyl-4-hydroxy-2-methylphenyl)-4-n-dodecylmercaptobutane, 1,1,5,5-tetra-(5-tert-butyl-4-hydroxy-2-methylphenyl)pentane.

1.7. O-, N- and S-benzyl compounds, for example 3, 5,3′,5′-tetra-tert-butyl-4,4′-dihydroxydibenzyl ether, octadecyl-4-hydroxy-3,5-dimethylbenzylmercaptoacetate, tri-decyl-4-hydroxy-3,5-di-tert-butylbenzylmercaptoacetate, tris(3,5-di-tert-butyl-4-hydroxybenzyl)amine, bis(4-tert-butyl-3-hydroxy-2,6-dimethylbenzyl)dithioterephthalate, bis(3,5-di-tert-butyl-4-hydroxybenzyl)sulfide, isooctyl-3,5-di-tert-butyl-4-hydroxybenzylmercaptoacetate.

1.8. Hydroxybenzylated malonates, for example dioctadecyl-2,2-bis(3,5-di-tert-butyl-2-hydroxybenzyl)malonate, di-octadecyl-2-(3-tert-butyl-4-hydroxy-5-methylbenzyl)malonate, di-dodecylmercaptoethyl-2,2-bis(3,5-di-tert-butyl-4-hydroxybenzyl)malonate, bis[4-(1,1,3,3-tetramethylbutyl)phenyl]-2,2-bis(3,5-di-tert-butyl-4-hydroxybenzyl)malonate.

1.9. Aromatic hydroxybenzyl compounds, for example 1,3,5-tris(3,5-di-tert-butyl-4-hydroxybenzyl)-2,4,6-trimethylbenzene, 1,4-bis(3,5-di-tert-butyl-4-hydroxybenzyl)-2,3,5,6-tetramethylbenzene, 2,4,6-tris(3,5-di-tert-butyl-4-hydroxybenzyl)phenol.

1.10. Triazine compounds, for example 2,4-bis(octylmercapto)-6-(3,5-di-tert-butyl-4-hydroxyanilino)-1,3,5-triazine, 2-octylmercapto-4,6-bis(3,5-di-tert-butyl-4-hydroxyanilino)-1,3,5-triazine, 2-octylmercapto-4,6-bis(3,5-di-tert-butyl-4-hydroxyphenoxy)-1,3,5-triazine, 2,4,6-tris(3,5-di-tert-butyl-4-hydroxyphenoxy)-1,2,3-triazine, 1,3,5-tris(3,5-di-tert-butyl-4-hydroxybenzyl)isocyanurate, 1,3,5-tris(4-tert-butyl-3-hydroxy-2,6-dimethylbenzyl)isocyanurate, 2,4,6-tris(3,5-di-tert-butyl-4-hydroxyphenylethyl)-1,3,5-triazine, 1,3,5-tris(3,5-di-tert-butyl-4-hydroxyphenylpropionyl)-hexahydro-1,3,5-triazine, 1,3,5-tris(3,5-dicyclohexyl-4-hydroxybenzyl)isocyanurate.

1.11. Benzylphosphonates, for example dimethyl-2,5-di-tert-butyl-4-hydroxybenzylphosphonate, diethyl-3,5-di-tert-butyl-4-hydroxybenzylphosphonate, dioctadecyl-3,5-di-tert-butyl-4-hydroxybenzylphosphonate, dioctadecyl-5-tert-butyl-4-hydroxy-3-methylbenzylphosphonate, the calcium salt of the monoethyl ester of 3,5-di-tert-butyl-4-hydroxybenzylphosphonic acid.

1.12. Acylaminophenols, for example 4-hydroxylauranilide, 4-hydroxystearanilide, octyl N-(3,5-di-tert-butyl-4-hydroxyphenyl)carbamate.

1.13. Esters of β-(3,5-di-tert-butyl-4-hydroxyphenyl)propionic acid with mono- or polyhydric alcohols, e.g. with methanol, ethanol, n-octanol, i-octanol, octadecanol, 1,6-hexanediol, 1,9-nonanediol, ethylene glycol, 1,2-propanediol, neopentyl glycol, thiodiethylene glycol, diethylene glycol, triethylene glycol, pentaerythritol, tris(hydroxyethyl)isocyanurate, N,N′-bis(hydroxyethyl)oxamide, 3-thiaundecanol, 3-thiapentadecanol, trimethylhexanediol, trimethylolpropane, 4-hydroxymethyl-1-phospha-2,6,7-trioxabicyclo[2.2.2]octane.

1.14. Esters of β-(5-tert-butyl-4-hydroxy-3-methylphenyl)propionic acid with mono- or polyhydric alcohols, e.g. with methanol, ethanol, n-octanol, i-octanol, octadecanol, 1,6-hexanediol, 1,9-nonanediol, ethylene glycol, 1,2-propanediol, neopentyl glycol, thiodiethylene glycol, diethylene glycol, triethylene glycol, pentaerythritol, tris(hydroxyethyl)isocyanurate, N,N′-bis(hydroxyethyl)oxamide, 3-thiaundecanol, 3-thiapentadecanol, trimethylhexanediol, trimethylolpropane, 4-hydroxymethyl-1-phospha-2,6,7-trioxabicyclo[2.2.2]octane; 3,9-bis[2-{3-(3-tert-butyl-4-hydroxy-5-methylphenyl)propionyloxy}-1,1-dimethylethyl]-2,4,8,10-tetraoxaspiro[5.5]undecane.

1.15. Esters of β-(3,5-dicyclohexyl-4-hydroxyphenyl)propionic acid with mono- or polyhydric alcohols, e.g. with methanol, ethanol, octanol, octadecanol, 1,6-hexanediol, 1,9-nonanediol, ethylene glycol, 1,2-propanediol, neopentyl glycol, thiodiethylene glycol, diethylene glycol, triethylene glycol, pentaerythritol, tris(hydroxyethyl)isocyanurate, N,N′-bis(hydroxyethyl)oxamide, 3-thiaundecanol, 3-thiapentadecanol, trimethylhexanediol, trimethylolpropane, 4-hydroxymethyl-1-phospha-2,6,7-trioxabicyclo[2.2.2]octane.

1.16. Esters of 3,5-di-tert-butyl-4-hydroxyphenyl acetic acid with mono- or polyhydric alcohols, e.g. with methanol, ethanol, octanol, octadecanol, 1,6-hexanediol, 1,9-nonanediol, ethylene glycol, 1,2-propanediol, neopentyl glycol, thiodiethylene glycol, diethylene glycol, triethylene glycol, pentaerythritol, tris(hydroxyethyl)isocyanurate, N,N′-bis(hydroxyethyl)oxamide, 3-thiaundecanol, 3-thiapentadecanol, trimethylhexanediol, trimethylolpropane, 4-hydroxymethyl-1-phospha-2,6,7-trioxabicyclo[2.2.2]octane.

1.17. Amides of β-(3,5-di-tert-butyl-4-hydroxyphenyl)propionic acid e.g. N,N′-bis(3,5-di-tert-butyl-4-hydroxyphenylpropionyl)hexamethylenediamide, N,N′-bis(3,5-di-tert-butyl-4-hydroxyphenylpropionyl)trimethylenediamide, N,N′-bis(3,5-di-tert-butyl-4-hydroxyphenylpropionyphydrazide, N,N′-bis[2-(3-[3,5-di-tert-butyl-4-hydroxyphenyl]propionyloxy)ethyl]oxamide (Naugard®XL-1, supplied by Uniroyal).

1.18. Ascorbic acid (vitamin C)

1.19. Aminic antioxidants, for example N,N′-di-isopropyl-p-phenylenediamine, N,N′-di-sec-butyl-p-phenylenediamine, N,N′-bis(1,4-dimethylpentyl)-p-phenylenediamine, N,N′-bis(1-ethyl-3-methylpentyl)-p-phenylenediamine, N,N′-bis(1-methylheptyl)-p-phenylenediamine, N,N′-dicyclohexyl-p-phenylenediamine, N,N′-diphenyl-p-phenylenediamine, N,N′-bis(2-naphthyl)-p-phenylenediamine, N-isopropyl-N′-phenyl-p-phenylenediamine, N-(1,3-dimethylbutyl)-N′-phenyl-p-phenylenediamine, N-(1-methylheptyl)-N′-phenyl-p-phenylenediamine, N-cyclohexyl-N′-phenyl-p-phenylenediamine, 4-(p-toluenesulfamoyl)diphenylamine, N,N′-dimethyl-N,N′-di-sec-butyl-p-phenylenediamine, diphenylamine, N-allyldiphenylamine, 4-isopropoxydiphenylamine, N-phenyl-1-naphthylamine, N-(4-tert-octylphenyl)-1-naphthylamine, N-phenyl-2-naphthylamine, octylated diphenylamine, for example p,p′-di-tert-octyldiphenylamine, 4-n-butylaminophenol, 4-butyrylaminophenol, 4-nonanoylaminophenol, 4-dodecanoylaminophenol, 4-octadecanoylaminophenol, bis(4-methoxyphenyl)amine, 2,6-di-tert-butyl-4-dimethylaminomethylphenol, 2,4′-diaminodiphenylmethane, 4,4′-diaminodiphenylmethane, N,N,N′,N′-tetramethyl-4,4′-diaminodiphenylmethane, 1,2-bis[(2-methylphenyl)amino]ethane, 1,2-bis(phenylamino)propane, (o-tolyl)biguanide, bis[4-(1′,3′-dimethylbutyl)phenyl]amine, tert-octylated N-phenyl-1-naphthylamine, a mixture of mono- and dialkylated tert-butyl/tert-octyldiphenylamines, a mixture of mono- and dialkylated nonyldiphenylamines, a mixture of mono- and dialkylated dodecyldiphenylamines, a mixture of mono- and dialkylated isopropyl/isohexyldiphenylamines, a mixture of mono- and dialkylated tert-butyldiphenylamines, 2,3-dihydro-3,3-dimethyl-4H-1,4-benzothiazine, phenothiazine, a mixture of mono- and dialkylated tert-butyl/tert-octylphenothiazines, a mixture of mono- and dialkylated tert-octyl-phenothiazines, N-allylphenothiazine, N,N,N′,N′-tetraphenyl-1,4-diaminobut-2-ene.

2. UV absorbers and light stabilizers

2.1. 2-(2′-Hydroxyphenyl)benzotriazoles, for example 2-(2′-hydroxy-5′-methylphenyl)benzotriazole, 2-(3′,5′-di-tert-butyl-2′-hydroxyphenyl)benzotriazole, 2-(5′-tert-butyl-2′-hydroxyphenyl)benzotriazole, 2-(2′-hydroxy-5′-(1,1,3,3-tetramethylbutyl)phenyl)benzotriazole, 2-(3′,5′-di-tert-butyl-2′-hydroxyphenyl)-5-chloro-benzotriazole, 2-(3′-tert-butyl-2′-hydroxy-5′-methylphenyl)-5-chloro-benzotriazole, 2-(3′-sec-butyl-5′-tert-butyl-2′-hydroxyphenyl)benzotriazole, 2-(2′-hydroxy-4′-octyloxyphenyl)benzotriazole, 2-(3′,5′-di-tert-amyl-2′-hydroxyphenyl)benzotriazole, 2-(3′,5′-bis-(α,α-dimethylbenzyl)-2′-hydroxyphenyl)benzotriazole, 2-(3′-tert-butyl-2′-hydroxy-5′-(2-octyloxycarbonylethyl)phenyl)-5-chloro-benzotriazole, 2-(3′-tert-butyl-5′-[2-(2-ethylhexyloxy)-carbonylethyl]-2′-hydroxyphenyl)-5-chloro-benzotriazole, 2-(3′-tert-butyl-2′-hydroxy-5′-(2-methoxycarbonylethyl)phenyl)-5-chloro-benzotriazole, 2-(3′-tert-butyl-2′-hydroxy-5′-(2-methoxycarbonylethyl)phenyl)benzotriazole, 2-(3′-tert-butyl-2′-hydroxy-5′-(2-octyloxycarbonylethyl)phenyl)benzotriazole, 2-(3′-tert-butyl-5′-[2-(2-ethylhexyloxy)carbonylethyl]-2′-hydroxyphenyl)benzotriazole, 2-(3′-dodecyl-2′-hydroxy-5′-methylphenyl)benzotriazole, 2-(3′-tert-butyl-2′-hydroxy-5′-(2-isooctyloxycarbonylethyl)phenylbenzotriazole, 2,2′-methylene-bis[4-(1,1,3,3-tetramethylbutyl)-6-benzotriazole-2-ylphenol]; the transesterification product of 2-[3′-tert-butyl-5′-(2-methoxycarbonylethyl)-2′-hydroxyphenyl]-2H-benzotriazole with polyethylene glycol 300;

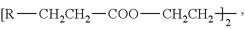

where R=3′-tert-butyl-4′-hydroxy-5′-2H-benzotriazol-2-ylphenyl, 2-[2′-hydroxy-3′-(α,α-dimethylbenzyl)-5′-(1,1,3,3-tetramethylbutyl)-phenyl]benzotriazole; 2-[2′-hydroxy-3′-(1,1,3,3-tetramethylbutyl)-5′-(α,α-dimethylbenzyl)-phenyl]benzotriazole.

2.2. Esters of substituted and unsubstituted benzoic acids, for example 4-tert-butyl-phenyl salicylate, phenyl salicylate, octylphenyl salicylate, dibenzoyl resorcinol, bis(4-tert-butylbenzoyl)resorcinol, benzoyl resorcinol, 2,4-di-tert-butylphenyl 3,5-di-tert-butyl-4-hydroxybenzoate, hexadecyl 3,5-di-tert-butyl-4-hydroxybenzoate, octadecyl 3,5-di-tert-butyl-4-hydroxybenzoate, 2-methyl-4,6-di-tert-butylphenyl 3,5-di-tert-butyl-4-hydroxybenzoate.

2.3. Acrylates, for example ethyl α-cyano-β,β-diphenylacrylate, isooctyl α-cyano-β,βdiphenylacrylate, methyl α-carbomethoxycinnamate, methyl α-cyano-β-methyl-p-methoxycinnamate, butyl α-cyano-β-methyl-p-methoxy-cinnamate, methyl α-carbomethoxy-p-methoxycinnamate, N-(β-carbomethoxy-β-cyanovinyl)-2-methylindoline, neopentyl tetra(α-cyano-β,β-diphenylacrylate.

2.4. Nickel compounds, for example nickel complexes of 2,2′-thio-bis[4-(1,1,3,3-tetramethylbutyl)phenol], such as the 1:1 or 1:2 complex, with or without additional ligands such as n-butylamine, triethanolamine or N-cyclohexyldiethanolamine, nickel dibutyldithiocarbamate, nickel salts of the monoalkyl esters, e.g. the methyl or ethyl ester, of 4-hydroxy-3,5-di-tert-butylbenzylphosphonic acid, nickel complexes of ketoximes, e.g. of 2-hydroxy-4-methylphenylundecylketoxime, nickel complexes of 1-phenyl-4-lauroyl-5-hydroxypyrazole, with or without additional ligands.

2.5. Oxamides, for example 4, 4′-dioctyloxyoxanilide, 2,2′-diethoxyoxanilide, 2,2′-dioctyloxy-5,5′-di-tert-butoxanilide, 2,2′-didodecyloxy-5,5′-di-tert-butoxanilide, 2-ethoxy-2′-ethyloxanilide, N,N′-bis(3-dimethylaminopropyl)oxamide, 2-ethoxy-5-tert-butyl-2′-ethoxanilide and its mixture with 2-ethoxy-2′-ethyl-5,4′-di-tert-butoxanilide, mixtures of o- and p-methoxy-disubstituted oxanilides and mixtures of o- and p-ethoxy-disubstituted oxanilides.

2.6. 2-(2-Hydroxyphenyl)-1,3,5-triazines, for example 2,4,6-tris(2-hydroxy-4-octyloxyphenyl)-1,3,5-triazine, 2-(2-hydroxy-4-octyloxyphenyl)-4,6-bis(2,4-dimethylphenyl)-1,3,5-triazine, 2-(2,4-dihydroxyphenyl)-4,6-bis(2,4-dimethylphenyl)-1,3,5-triazine, 2,4-bis(2-hydroxy-4-propyloxyphenyl)-6-(2,4-dimethylphenyl)-1,3,5-triazine, 2-(2-hydroxy-4-octyloxyphenyl)-4,6-bis(4-methylphenyl)-1,3,5-triazine, 2-(2-hydroxy-4-dodecyloxyphenyl)-4,6-bis(2,4-dimethylphenyl)-1,3,5-triazine, 2-(2-hydroxy-4-tridecyloxyphenyl)-4,6-bis(2,4-dimethylphenyl)-1,3,5-triazine, 2-[2-hydroxy-4-(2-hydroxy-3-butyloxypropoxy)phenyl]-4,6-bis(2,4-dimethyl)-1,3,5-triazine, 2-[2-hydroxy-4-(2-hydroxy-3-octyloxypropyloxy)phenyl]-4,6-bis(2,4-dimethyl)-1,3,5-triazine, 2-[4-(dodecyloxy/tridecyloxy-2-hydroxypropoxy)-2-hydroxyphenyl]-4,6-bis(2,4-dimethylphenyl)-1,3,5-triazine, 2-[2-hydroxy-4-(2-hydroxy-3-dodecyloxypropoxy)phenyl]-4,6-bis(2,4-dimethylphenyl)-1,3,5-triazine, 2-(2-hydroxy-4-hexyloxy)phenyl-4,6-diphenyl-1,3,5-triazine, 2-(2-hydroxy-4-methoxyphenyl)-4,6-diphenyl-1,3,5-triazine, 2,4,6-tris[2-hydroxy-4-(3-butoxy-2-hydroxypropoxy)phenyl]-1,3,5-triazine, 2-(2-hydroxyphenyl)-4-(4-methoxyphenyl)-6-phenyl-1,3,5-triazine, 2-{2-hydroxy-4-[3-(2-ethylhexyl-1-oxy)-2-hydroxypropyloxy]phenyl}-4,6-bis(2,4-dimethylphenyl)-1,3,5-triazine, 2,4-bis(4-[2-ethylhexyloxy]-2-hydroxyphenyl)-6-(4-methoxyphenyl)-1,3,5-triazine.

2.7. Quinoline derivatives such as e.g. the commercially available UVI® NUL® S-Pack.

3. Metal deactivators, for example N,N′-diphenyloxamide, N-salicylal-N′-salicyloyl hydrazine, N,N′-bis(salicyloyl)hydrazine, N,N′-bis(3,5-di-tert-butyl-4-hydroxyphenylpropionyl)hydrazine, 3-salicyloylamino-1,2,4-triazole, bis(benzylidene)oxalyl dihydrazide, oxanilide, isophthaloyl dihydrazide, sebacoyl bisphenylhydrazide, N,N′-diacetyladipoyl dihydrazide, N,N′-bis(salicyloyl)oxalyl dihydrazide, N,N′-bis(salicyloyl)thiopropionyl dihydrazide.

4. Phosphites and phosphonites, for example triphenyl phosphite, diphenylalkyl phosphites, phenyldialkyl phosphites, tris(nonylphenyl) phosphite, trilauryl phosphite, trioctadecyl phosphite, distearylpentaerythritol diphosphite, tris(2,4-di-tert-butylphenyl) phosphite, diisodecyl pentaerythritol diphosphite, bis(2,4-di-tert-butylphenyl)pentaerythritol diphosphite, bis(2,4-di-cumylphenyl)pentaerythritol diphosphite, bis(2,6-di-tert-butyl-4-methylphenyl)pentaerythritol diphosphite, diisodecyloxypentaerythritol diphosphite, bis(2,4-di-tert-butyl-6-methylphenyl)pentaerythritol diphosphite, bis(2,4,6-tris(tert-butylphenyl)pentaerythritol diphosphite, tristearyl sorbitol triphosphite, tetrakis(2,4-di-tert-butylphenyl) 4,4′-biphenylene diphosphonite, 6-isooctyloxy-2,4,8,10-tetra-tert-butyl-12H-dibenz[d,g]-1,3,2-dioxaphosphocin, bis(2,4-di-tert-butyl-6-methylphenyl)methyl phosphite, bis(2,4-di-tert-butyl-6-methylphenyl)ethyl phosphite, 6-fluoro-2,4,8,10-tetra-tert-butyl-12-methyl-dibenz[d,g]-1,3,2-dioxaphosphocin, 2,2′,2″-nitrilo[triethyltris(3,3′,5,5′-tetra-tert-butyl-1,1′-biphenyl-2,2′-diyl)phosphite], 2-ethylhexyl(3,3′,5,5′-tetra-tert-butyl-1,1′-biphenyl-2,2′-diyl)phosphite, 5-butyl-5-ethyl-2-(2,4,6-tri-tert-butylphenoxy)-1,3,2-dioxaphosphirane.

The following phosphites are especially preferred:

Tris(2,4-di-tert-butylphenyl) phosphite (Irgafos®168, Ciba Specialty Chemicals Inc.), tris(nonylphenyl) phosphite,

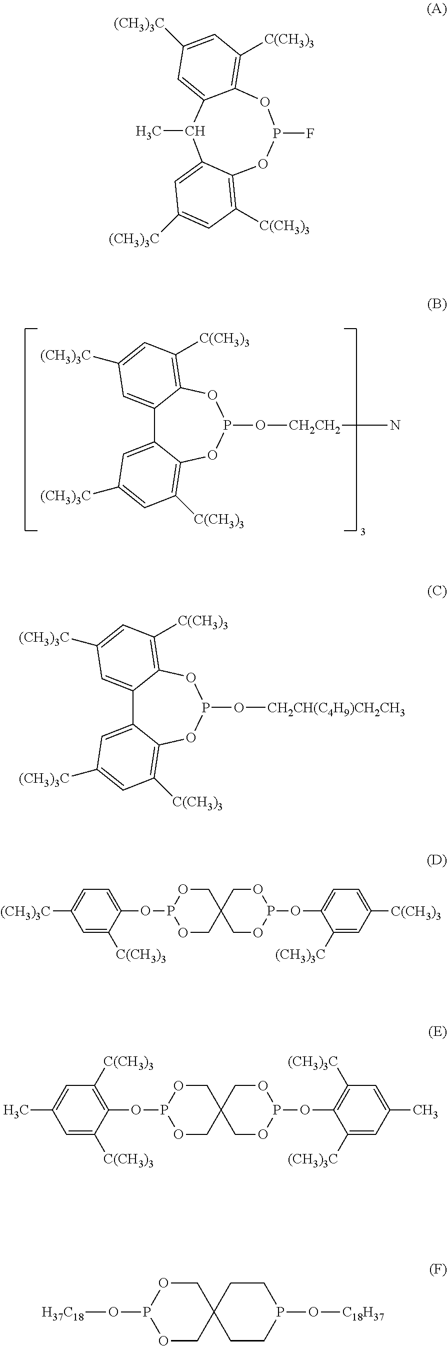

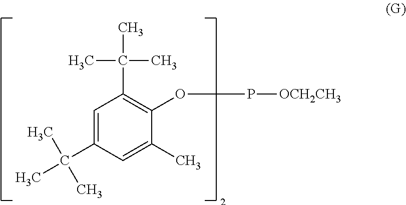

5. Hydroxylamines, for example N,N-dibenzylhydroxylamine, N,N-diethylhydroxylamine, N,N-dioctylhydroxylamine, N,N-dilaurylhydroxylamine, N,N-ditetradecylhydroxylamine, N,N-dihexadecylhydroxylamine, N,N-dioctadecylhydroxylamine, N-hexadecyl-N-octadecylhydroxylamine, N-heptadecyl-N-octadecylhydroxylamine, N,N-dialkylhydroxylamine derived from hydrogenated tallow amine.

6. Nitrones, for example, N-benzyl-alpha-phenylnitrone, N-ethyl-alpha-methylnitrone, N-octyl-alpha-heptylnitrone, N-lauryl-alpha-undecylnitrone, N-tetradecyl-alpha-tridecylnnitrone, N-hexadecyl-alpha-pentadecylnitrone, N-octadecyl-alpha-heptadecynitrone, N-hexadecyl-alpha-heptadecylnitrone, N-ocatadecyl-alpha-pentadecylnitrone, N-heptadecyl-alpha-heptadecylnitrone, N-octadecyl-alpha-hexadecylnitrone, nitrone derived from N,N-dialkylhydroxylamine derived from hydrogenated tallow amine.

7. Thiosynergists, for example dilauryl thiodipropionate, dimistryl thiodipropionate, distearyl thiodipropionate or distearyl disulfide.

8. Peroxide scavengers, for example esters of β-thiodipropionic acid, for example the lauryl, stearyl, myristyl or tridecyl esters, mercaptobenzimidazole or the zinc salt of 2-mercaptobenzimidazole, zinc dibutyldithiocarbamate, dioctadecyl disulfide, pentaerythritol tetrakis(β-dodecylmercapto)propionate.

9. Peroxide, for example decanoyl peroxide, lauroyl peroxide, succinic acid peroxide, benzoyl peroxide, dicumyl peroxide, 2,5-di(t-butylperoxy)-2,5-dimethylhexane, t-butyl cumyl peroxide, α,α′-bis(t-butylperoxy)diisopropylbenzene, di(t-amyl)peroxide, di(t-butyl)peroxide, 2,5-di(t-butylperoxy)-2,5-dimethyl-3-hexyne, 1,1-di(t-butylperoxy)-3,3,5-trimethylcyclohexane, 1,1-di(t-butylperoxy)-cyclohexane, 1,1-di(t-amylperoxy)cyclohexane, n-butyl 4,4-di(t-butylperoxy)valerate, ethyl 3,3-di-(t-amylperoxy)butanoate, ethyl 3,3-di-(t-butylperoxy)butyrate, tert-butylperoxy 2-ethylhexyl carbonate.

10. Polyamide stabilizers, for example copper salts in combination with iodides and/or phosphorus compounds and salts of divalent manganese.

11. Basic co-stabilizers, for example melamine, polyvinylpyrrolidone, dicyandiamide, triallyl cyanurate, urea derivatives, hydrazine derivatives, amines, polyamides, polyurethanes, alkali metal salts and alkaline earth metal salts of higher fatty acids, for example calcium stearate, zinc stearate, magnesium behenate, magnesium stearate, sodium ricinoleate and potassium palmitate, antimony pyrocatecholate or zinc pyrocatecholate.

12. Neutralizers, for example MgO, CaO, ZnO, Mg(OH)₂, Ca(OH)₂, Ba(OH)₂, Al(OH)₃, MgCO₃, CaCO₃, hydrotalcite.

13. Nucleating agents, for example inorganic substances, such as talcum, metal oxides, such as titanium dioxide or magnesium oxide, phosphates, carbonates or sulfates of, preferably, alkaline earth metals; organic compounds, such as mono- or polycarboxylic acids and the salts thereof, e.g. 4-tert-butylbenzoic acid, adipic acid, diphenylacetic acid, sodium succinate or sodium benzoate; polymeric compounds, such as ionic copolymers (ionomers). Especially preferred are 1,3:2,4-bis(3′,4′-dimethylbenzylidene)sorbitol, 1,3:2,4-di(paramethyldibenzylidene)sorbitol, and 1,3:2,4-di(benzylidene)sorbitol.

14. Fillers and reinforcing agents, for example calcium carbonate, silicates, glass fibres, glass beads, asbestos, talc, kaolin, mica, barium sulfate, metal oxides and hydroxides, carbon black, graphite, wood flour and flours or fibers of other natural products, synthetic fibers.

15. Other additives, for example plasticisers, lubricants, emulsifiers, pigments, rheology additives, catalysts, flow-control agents, flameproofing agents, antistatic agents and blowing agents.

16. Benzofuranones and indolinones, for example those disclosed in U.S. Pat. No. 4,325,863; U.S. Pat. No. 4,338,244; U.S. Pat. No. 5,175,312; U.S. Pat. No. 5,216,052; U.S. Pat. No. 5,252,643; DE-A-4316611; DE-A-4316622; DE-A-4316876; EP-A-0589839, EP-A-0591102; EP-A-1291384 or 3-[4-(2-acetoxyethoxy)phenyl]-5,7-di-tert-butylbenzofuran-2-one, 5,7-di-tert-butyl-3-[4-(2-stearoyloxyethoxy)phenyl]benzofuran-2-one, 3,3′-bis[5,7-di-tert-butyl-3-(4-[2-hydroxyethoxy]phenyl)benzofuran-2-one], 5,7-di-tert-butyl-3-(4-ethoxyphenyl)benzofuran-2-one, 3-(4-acetoxy-3,5-dimethylphenyl)-5,7-di-tert-butylbenzofuran-2-one, 3-(3,5-dimethyl-4-pivaloyloxyphenyl)-5,7-di-tert-butylbenzofuran-2-one, 3-(3,4-dimethylphenyl)-5,7-di-tert-butylbenzofuran-2-one, 3-(2,3-dimethylphenyl)-5,7-di-tert-butylbenzofuran-2-one, 3-(2-acetyl-5-isooctylphenyl)-5-isooctylbenzofuran-2-one.

In general, the conventional additive may be present in the layer or layers of component (2) in an amount of, for example, 0.001 to 20% or 0.01 to 20%, preferably 0.001 to 5% or 0.01 to 5%, relative to the weight of Component (A).

Of interest is a photovoltaic module wherein the layer or layers of component (2) contain one or more further components selected from the group consisting of

(D) a benzotriazole UV absorber, preferably one of those listed above under item 2.1.

(E) a phenolic antioxidant, preferably one of those listed above under item 1.

(F) a basic co-additive, for example one of those listed above under item 11, and

(G) a neutralizer, for example one of those listed above under item 12.

A particularly preferred benzotriazole UV absorber has the following structure:

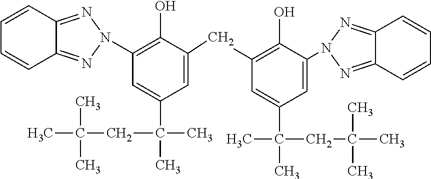

The following preferences relate to the layer or layers of present component (2):

Component (B) is present in an amount of e.g. 0.01 to 10%, preferably 0.05 to 2%, relative to the weight of component (A).

Component (C) is optionally present in an amount of preferably 0.01 to 5%, in particular 0.05 to 1%, relative to the weight of component (A).

Component (D) is optionally present in an amount of preferably 0.01 to 10%, in particular 0.05 to 2%, relative to the weight of component (A).

Component (E) is optionally present in an amount of preferably 0.01 to 1%, in particular 0.01 to 0.5%, relative to the weight of component (A).

Component (F) is optionally present in an amount of preferably 0.01 to 10%, relative to the weight of component (A).

Component (G) is optionally present in an amount of preferably 0.01 to 10%, in particular 0.05 to 2%, relative to the weight of component (A).

The weight ratio of the two different compounds selected from the group consisting of the compounds of the formulae (B-I) and (B-II) is for example 1:100 to 100:1, preferably 1:10 to 10:1 or 1:5 to 5:1, in particular 1:3 to 3:1 or 1:2 to 2:1 or 1:1.

The layer or layers of present component (2) have for example a thickness of 10 to 2000 μm, in particular 50 to 1000 μm.

The layer or layers of present component (2) have excellent optical properties such as optical transparency, mechanical strength high enough to prevent e.g. contraction of a polarizer with high contractability, thermal resistance which can endure the high temperature which is applied during processes, and the like.

The layer or layers of present component (2) preferably have a low haze value of e.g. less than 1 (determined at a 20 μm film) according to ASTM D 1003.

If desired, the layer or layers of present component (2) may be subjected to a corona treatment of the surface. This is advantageous for improving the mutual adhesiveness; particularly, in the case of providing a surface treatment such as coating processing to the film surface, or in the case of laminating another film by using an adhesive.

Another embodiment of the present invention is the use of component (B) as defined above for stabilizing one of more synthetic polymer layers being present in a photovoltaic module.

A further embodiment of the present invention is a photovoltaic module comprising the components:

(1) a photovoltaic semiconductor and

(2) one or more layers containing
(A) a crosslinked ethylene vinyl acetate copolymer and
(B) a compound of the formula (B-I-a).

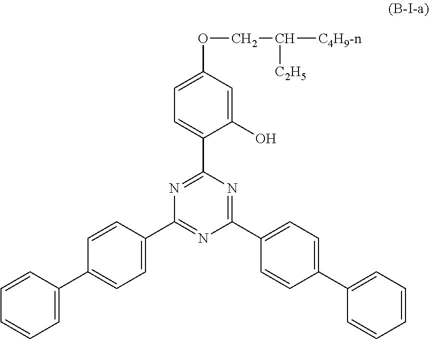

The preferences described above can also be applied in appropriate manner to this embodiment of the present invention.

The examples below illustrate the invention in greater detail. All percentages and parts are by weight, unless stated otherwise.

### Additives Tested:

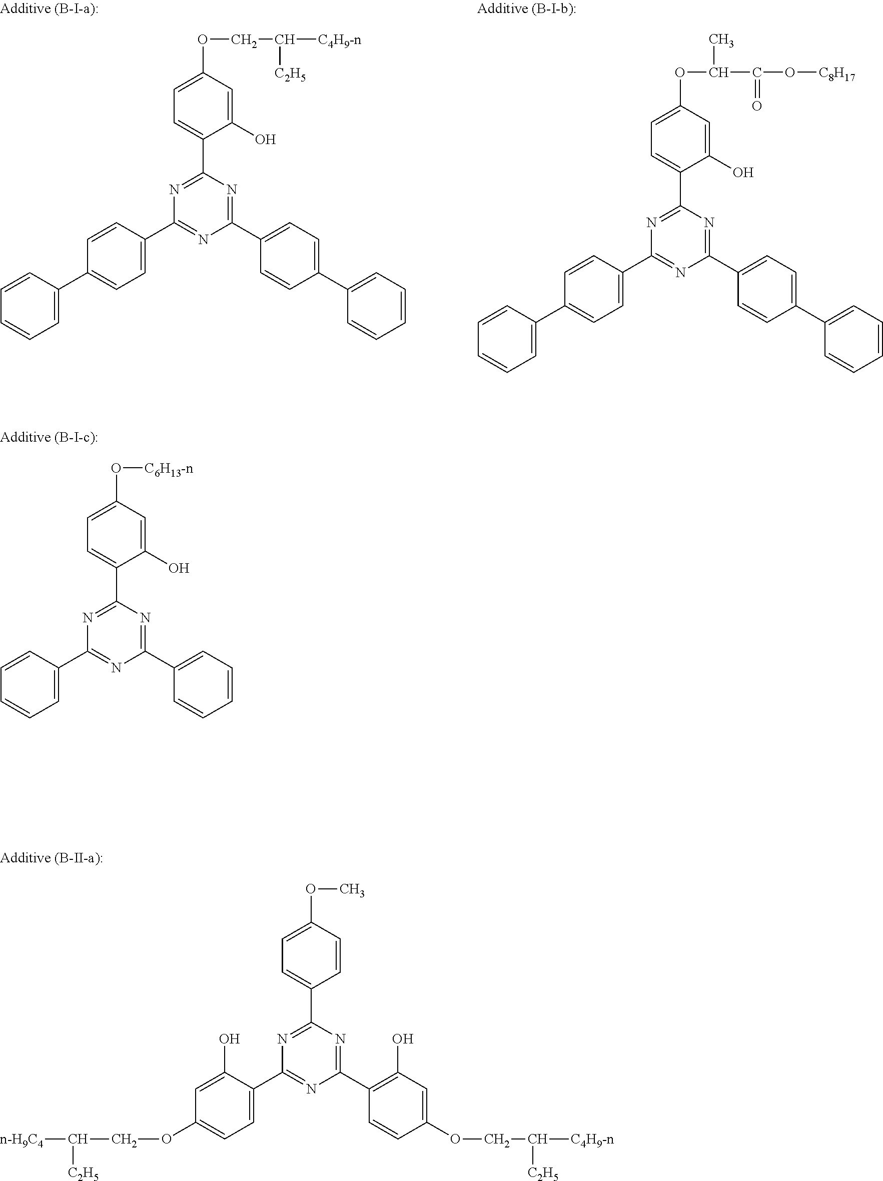

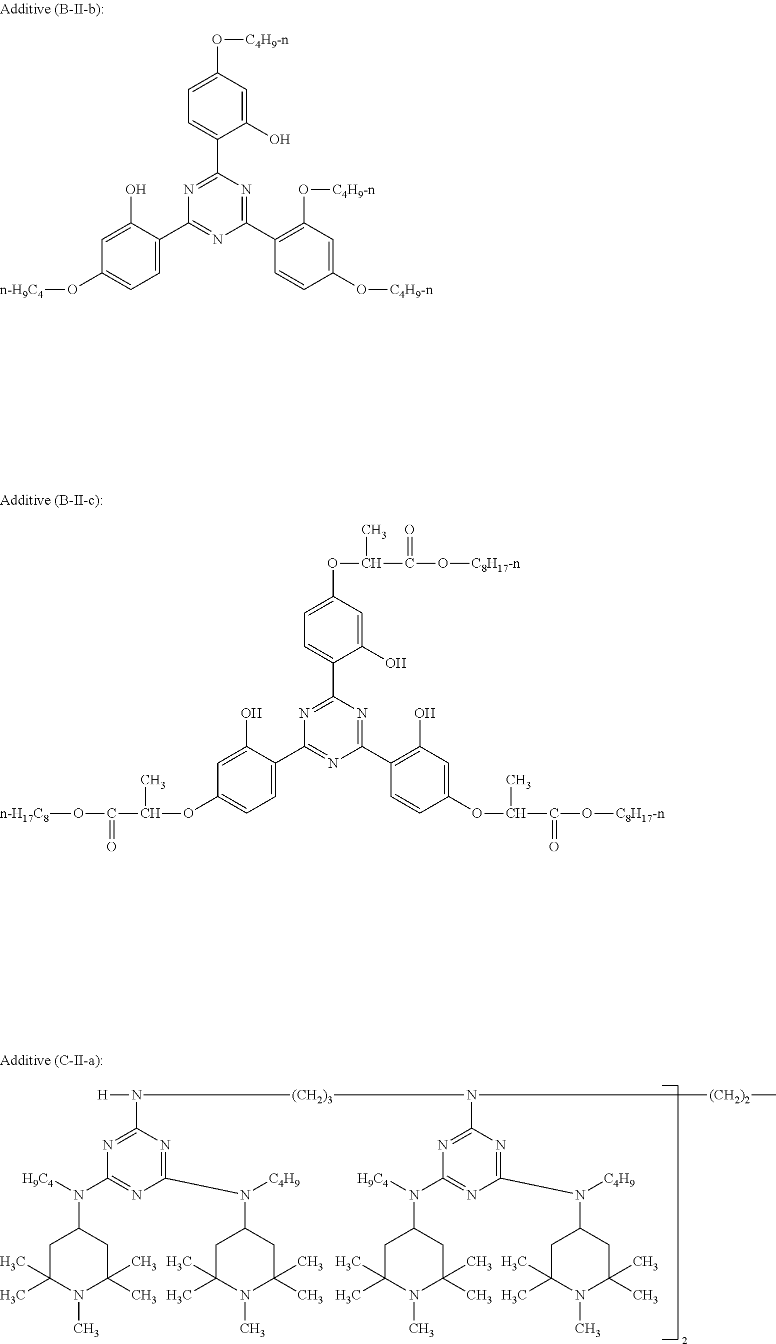

### Determination of Synergism:

The synergistic effect of two coadditivs ((α) and (β)) is determined by a comparison of the calculated YI (Yellowness Index) with the actually measured YI. The YI values are calculated on the basis of the additivity law (B. Ranby and J. F. Rabek; Photodegradation, Photo-oxidation and Photostabilization of Polymers, Principles and Applications, John Wiley & Sons, London, New York, Sydney, Toronto, 1975, pages 418 and 419) according to the following equation:

$$Expected stabilizing activity = \frac{\begin{matrix}Stabilizing activity of 100 \% ( α ) + \\ stabilizing activity of 100 \% ( β )\end{matrix}}{2}$$

There is a synergistic effect for the two coadditivs in question, when YI_{measured}<YI_{calculated}.

### EXAMPLE 1

### Stabilization of Cyclic Olefin Polymer Films

10 g of commercial cyclic olefin polymer (Zeonex®480 R, manufactured by Nippon Zeon Co., Ltd.,) are solved in 40 g of a mixture of chloroform (70%), cyclohexane (20%) and toluene (10%) with the additives indicated in Table 1 at room temperature. Then, 5 g of the solution are poured on a crystal plate and the solution is equally spread on the crystal plate by Erichen®casting machine at room temperature. After 10 min evaporation of the solvent, a 20 micron solution cast film is obtained.

Accelerated weathering is performed using an Atlas Ci65A Weather-O-meter, operated in dry mode (ASTM G 26 C).

After regular intervals, the yellowness indices (YI) according to DIN 6167 are determined by means of a Spectraflash®SF 600 Plus. The results are listed in Table 1.

TABLE 1
YI of 20 micron cyclic olefin polymer films after weathering.

| | YI*⁾ after hours (h) weathering | | |
|---|---|---|---|
| Additive(s) | 0 h | 258 h | 497 h |
| 0.2% of Additive (B-I-c) | 0.3 | 0.5 | 0.8 |
| 0.2% of Additive | 1.1 | 2.5 | 3.2 |
| (B-II-c) | | | |
| 0.1% of Additive (B-I-c) | 0.7 | 1.5 | 2.0 |
| plus | (calculated) | (calculated | (calculated) |
| 0.1% of Additive | 0.4 | 0.9 | 1.4 |
| (B-II-c) | (measured) | (measured) | (measured) |

*⁾Low values are desired.

### EXAMPLE 2

### Stabilization of poly(methyl methacrylate)

10 g of a poly(methyl methacrylate) (Plexiglas® 7 N, manufactured by Evonik) are solved in 40 g of dichloromethane with the additives indicated in Table 2 at room temperature. Then, 5 g of the solution are poured on a crystal plate and the solution is equally spread on the crystal plate by an Ericheecasting machine at room temperature. After 10 min evaporation of the solvent, a 20 micron solution cast film is obtained.

Accelerated weathering is performed using an Atlas Ci65A Weather-O-meter, operated in dry mode (ASTM G 26 C).

After regular intervals, the yellowness indices (YI) according to DIN 6167 are determined by means of a Spectraflash®SF 600 Plus. The results are listed in Table 2.

TABLE 2
YI of 20 micron poly (methylmethacrylate) films after weathering.

| | YI*⁾ after hours (h) weathering | | |
|---|---|---|---|
| Additive(s) | 0 h | 234 h | 498 h |
| 0.5% of Additive (B-I-a) plus | 0.6 | 8.5 | 9.5 |
| 0.5% of Additive (B-II-b) | | | |
| 0.5% of Additive (B-I-a) plus | 0.6 | 1.3 | 1.6 |
| 0.5% of Additive (B-II-b) plus | | | |
| 0.3% of Additive (C-II-a) | | | |

*⁾Low values are desired.

### EXAMPLE 3

### Stabilization of an Extrusion Film Sample of Polycarbonate

Grinded commercial polycarbonate (Makrolon®3108 FBL, manufactured by Bayer Material Science) is dried in a vacuum drier (Vacutherm 1400) for 6 hours at 120° C. and mixed with the compounds indicated in Table 3 in an inner mixer (MTI/M20 FU) at 80° C. The mixture is compounded at 280° C. with a twin-screw extruder (Berstorff ZE 25×32D). After drying for 6 hours at 120° C., the composition is processed at 280° C. with a twin-screw extruder (Berstorff ZE 25×32D) again. After further drying of the composition for 6 hours at 120° C., a 0.1 mm film is obtained by means of an extruder (Collin CR-136/350) at 280° C.

Accelerated weathering is performed using an Atlas Ci65A Weather-O-meter, operated in wet mode (ASTM G 26 A).

Initial and after 257 h, the yellowness indeces (YI) are measured with a Spectraflash SF 600 Plus according to DIN 6167.

The results are listed in Table 3.

TABLE 3
YI of 0.1 mm polycarbonate films after weathering.

| | YI*⁾ after hours (h) weathering | |
|---|---|---|
| Additive(s) | 0 h | 257 h |
| 1% of Additive (B-I-a) | 2.0 | 2.2 |
| 1% of Additive (B-II-b) | 2.2 | 2.6 |
| 0.5% of Additive (B-I-a) plus | 2.1 (calculated) | 2.4 (calculated |
| 0.5% of Additive (B-II-b) | 2.0 (measured) | 2.3 (measured) |

*⁾Low values are desired.

### EXAMPLE 4

### Stabilization of Crosslinked Ethylene Vinyl Acetate Copolymer

Commercial crosslinked ethylene vinyl acetate copolymer (EVA; ELVAX® PV 1400, manufactured by DuPont) is soaked with peroxide (Luperox® 101, manufactured by Arkema) at room temperature. The soaked EVA pellet is compounded with the additive listed in Table 4 at a temperature below 70° C. with a calendaring mixer (Schwabenthan®, 0.5 mm compressed crosslinked EVA sheet is prepared by means of a compression molding machine (Suter®) at 150° C. for 10 minutes.

Accelerated weathering is performed using an Eye Super UV tester, SUV-W151 (Iwasaki Electric Co., Ltd.), operated with 100 mW/cm² irradiance, 63° C. black panel temperature and 50% humidity without water spray.

Initial and after the indicated intervals, the yellowness indexes (YI) is measured with a Spectrophotometer (Konika-Minolta CM-3700d).

The results are listed in Table 4.

TABLE 4
YI of 0.5 mm EVA sheet after weathering.

| | YI*⁾ after hours (h) weathering | |
|---|---|---|
| Additive(s) | 0 h | 100 h |
| 3% of Additive (B-I-a) | 3.4 | 2.7 |
| 3% of Additive (B-II-a) | 4.8 | 3.4 |
| 1.5% of Additive (B-I-a) plus | 4.1 (calculated) | 3.1 (calculated) |
| 1.5% of Additive (B-II-a) | 2.3 (measured) | 2.5 (measured) |

*⁾Low values are desired.

### EXAMPLE 5

### Dispersion of UV Absorbers in Poly(ethylene-co-vinylacetate)

100 parts of pellets of ELVAX®PV 1400 (DuPont Ltd; poly(ethylene-co-vinylacetate) with 32% relative weight content of vinyl acetate) and the respective relative weight amount of additive according to Table 5 are compounded at 70° C. and 150° C. for 5 minutes by a mixer (Plast-Corder, Brabender). The prepared compounded material is transformed by a compression molding machine (Suter Inc.) at 70° C. for 3 minutes to a compressed sheet of 0.5 mm thickness. A vacuum, i.e. a pressure lower than atmospheric pressure, is not applied during this sheet preparation.

In the prepared sheet, the visible particles which are larger than 0.25 mm are counted. The result is listed in Table 5.

TABLE 5

| | Additive added prior to | Number of particles >0.25 mm | |
|---|---|---|---|
| | compounding in relation to 100 | compounded | compounded at |
| Sheet | parts of pellets | at 70° C. | 150° C. |
| No. 1 | 0.2 parts of Additive (B-I-a) + | None | None |
| | 0.2 parts of Additive (B-II-a) | | |
| No. 2 | 0.2 parts of Additive (B-I-a) + | None | None |
| | 0.2 parts of Additive (B-II-b) | | |

### EXAMPLE 6

### Stabilization of Crosslinked poly(ethylene-co-vinylacetate) in a Crystalline Silicon Photovoltaic Module

### Sheet Production:

100 parts of pellets of ELVAX®PV 1400 (DuPont Ltd, poly(ethylene-co-vinylacetate) with 32% relative weight content of vinyl acetate) are soaked with 1 part liquid Luperox 101 (RTM Arkema Inc., containing 2,5-dimethyl-2,5-di-(tert-butylperoxy)hexane [CAS-No. 78-63-7]) without a further solvent in a rotating glass flask for 1-2 hours at room temperature.

The soaked pellets and the respective relative weight amount of additives according to Table 6 are compounded below 70° C. for 10 minutes by a calendaring mixer (Schwabenthan Inc.). The prepared compounded material is transformed by a compression molding machine (Suter Inc.) at 70° C. for 3 minutes to a compressed sheet of 0.5 mm thickness. A vacuum, i.e. a pressure lower than atmospheric pressure, is not applied during this sheet preparation.

### Module Production:

In a laminator (Meier Group), on top of a glass (Glas Mayer), an aforementiond EVA sheet, crystalline silicon cell (Q6LTT3 by Qcells), an aforementioned EVA sheet and a back-sheet (Type 2442 Thickness 0.17 mm by Isovolta) are layered. After a programmed lamination process (lamination temperature: 140° C., for 1 hour under vacuum), a module is obtained.

### Weathering Test:

The prepared module is exposed to an accelerated weathering test, which is performed using an Eye Super UV tester, SUV-W151 (Iwasaki Electric Co. Inc.), operated with 100 mW/cm² irradiance, 63° C. black panel temperature, 50% humidity and without water spray.

Initially and after regular intervals, the open circuit voltage (Voc) of the module is measured compliant to Japanese Industry Standard JIS C 8914 with a solar simulator, PEC-L11 (Peccell Technologies Inc.) and a source meter, KEITH LEY 2400 Digital SourceMeter (Keithley Instruments Inc.) The maintenance of each value is desired.

TABLE 6

| | Additive mixture added prior to |
|---|---|
| | compounding in relation to 100 parts of |
| Sheet | soaked pellets |
| No. 1 | 0.2 parts of Additive (B-I-a) + |
| | 0.2 parts of Additive (B-II-a) |
| No. 2 | 0.2 parts of Additive (B-I-a) + |
| | 0.2 parts of Additive (B-II-b) |

The results obtained show a good stabilizing effect of the additive mixtures indicated in the above table.

1. A photovoltaic module comprising
(1) a photovoltaic semiconductor;
(2) one or more layers containing
(A) independently of one another a synthetic polymer and
(B) a mixture containing two or more different compounds selected from the group consisting of compounds of formulae (B-I) and (B-II); 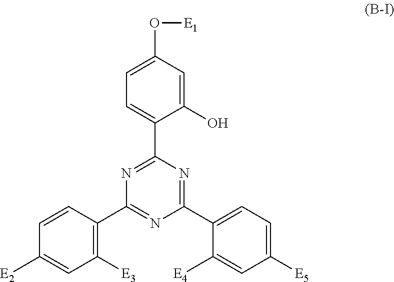
wherein
E₁ is hydrogen, C₁-C₁₈alkyl or C₁-C₁₈alkyl substituted by 1, 2 or 3 radicals selected from the group consisting of —OH, C₂-C₁₈alkenyloxy, —C(O)OX₁ and —OC(O)X₂ with X₁ and X₂ being independently C₁-C₁₈alkyl; C₃-C₅₀alkyl interrupted by oxygen or C₃-C₅₀hydroxyalkyl interrupted by oxygen; and
E₂, E₃, E₄ and E₅ are independently hydrogen, C₁-C₁₈alkyl, phenyl or phenyl substituted by 1, 2 or 3 C₁-C₄alkyl; 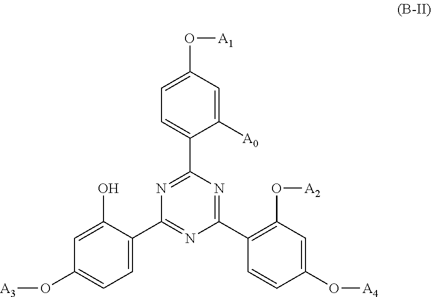
wherein
A₀ is hydrogen or —OH; and
A₁, A₂, A₃ and A₄ are independently hydrogen, C₁-C₁₈alkyl or C₁-C₁₈alkyl substituted by 1, 2 or 3 radicals selected from the group consisting of —OH, C₂-C₁₈alkenyloxy, —C(O)OY₁ and —OC(O)Y₂ with Y₁ and Y₂ being independently C₁-C₁₈alkyl; C₃-C₅₀alkyl interrupted by oxygen or C₃-C₅₀hydroxyalkyl interrupted by oxygen;
and optionally
(C) at least one 2,2,6,6-tetramethylpiperidine derivative.

2. A photovoltaic module according to claim 1 wherein
the synthetic polymer (A) is selected from
a linear or crosslinked polyolefin homopolymer,
a cyclic olefin homopolymer,
a cyclic olefin copolymer,
a linear or crosslinked polyolefin copolymer,
a poly(vinyl butyral),
a crosslinked ethylene vinyl acetate copolymer,
a polyester,
a polycarbonate,
a polyurethane,
a fluorinated polymer,
a poly(methyl methacrylate) and
a polysiloxane.

3. A photovoltaic module according to claim 1 wherein
the layer or layers of component (2) are selected from
(2-a) a front support layer,
(2-b) an encapsulating layer and
(2-c) a back substrate layer.

4. A photovoltaic module according to claim 3
comprising an encapsulating layer (2-b) which contains a synthetic polymer (A) selected from a linear or crosslinked polyolefin homopolymer, a linear or crosslinked polyolefin copolymer, a cyclic olefin homopolymer, a cyclic olefin copolymer, a poly(vinyl butyral), a crosslinked ethylene vinyl acetate copolymer, a polyurethane and a polysiloxane.

5. A photovoltaic module according to claim 3
comprising a back substrate layer (2-c) which contains a synthetic polymer (A) selected from a polyester, a polyamide and a fluorinated polymer.

6. A photovoltaic module according to claim 1 wherein
the photovoltaic semiconductor (1) contains a crystalline silicon or an amorphous silicon.

7. A photovoltaic module according to claim 1 wherein the compounds of formula (B-I) are selected from formulae (B-I-a), (B-I-b), (B-I-c), (B-I-d), (B-I-e) and (B-I-f) and the compounds of formula (B-II) are selected from formulae (B-II-a), (B-II-b) and (B-II-c)

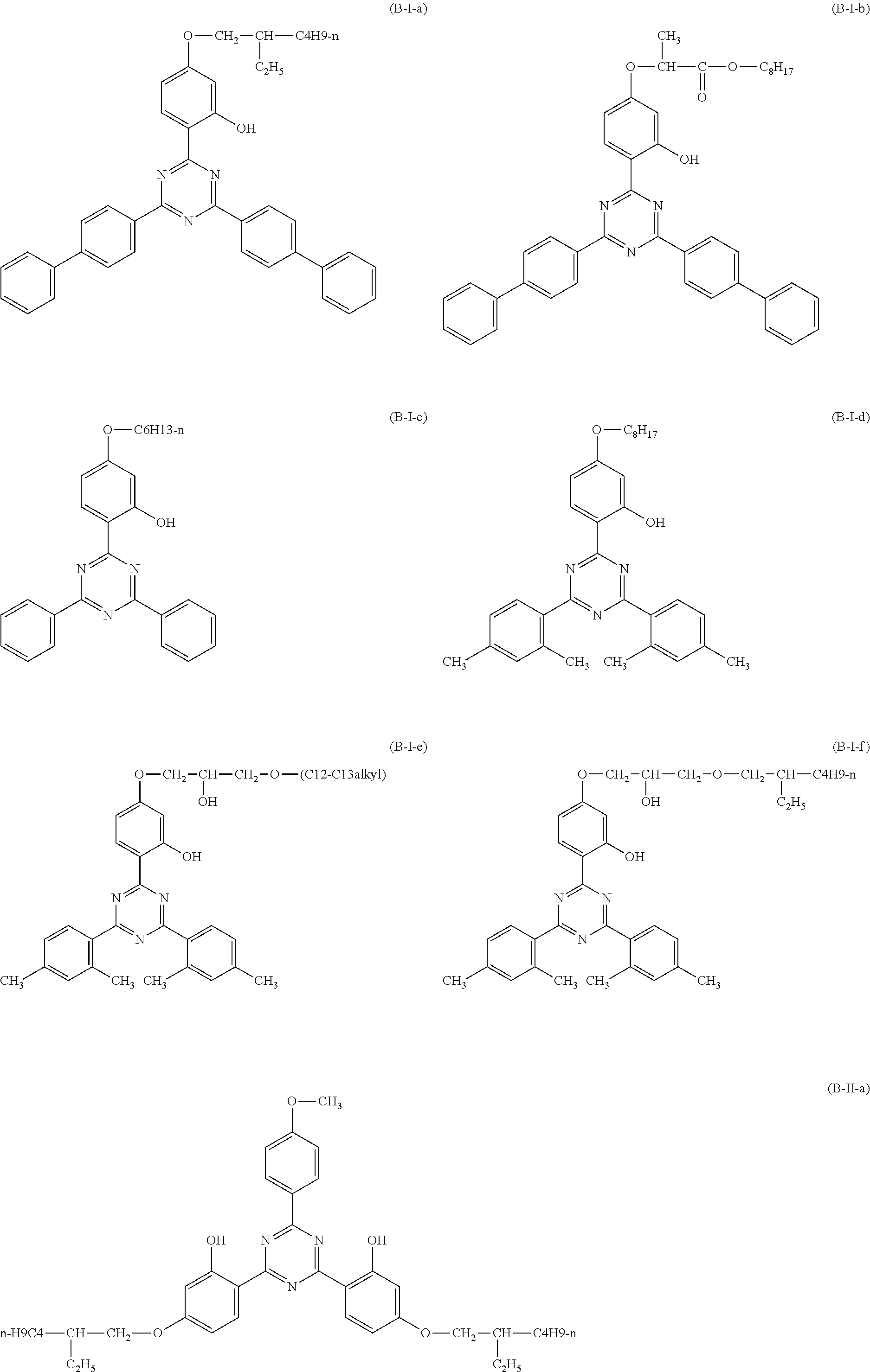

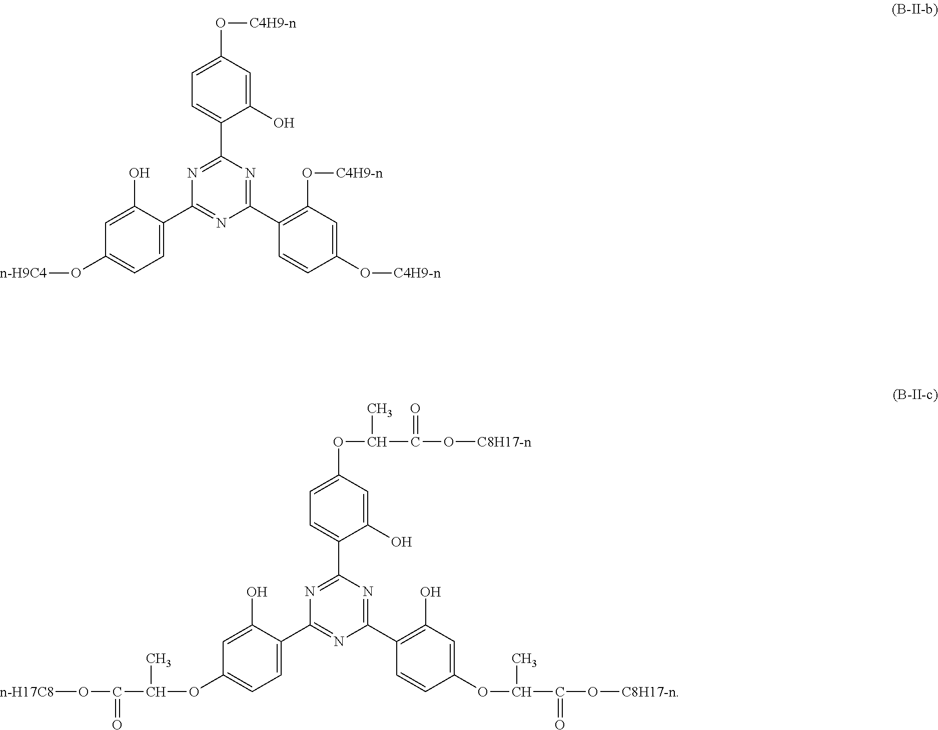

8. A photovoltaic module according to claim 7 wherein component (B) is
a mixture of the compounds (B-I-a) and (B-II-a),
a mixture of the compounds (B-I-a) and (B-II-b) or
a mixture of the compounds (B-I-c) and (B-II-c).

9. A photovoltaic module according to claim 1 comprising component (C) which is a compound of formula (C-I-a), (C-I-b), (C-I-c), (C-I-d) (C-II), (C-III) or (C-IV) 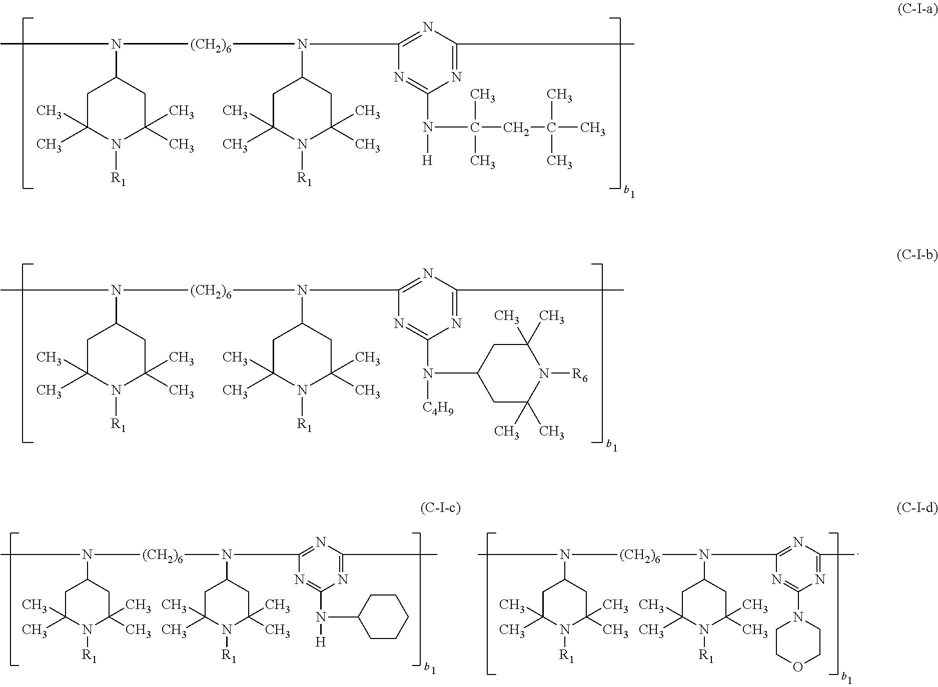
wherein b₁ is a number from 2 to 20 and the radicals R₁ are independently hydrogen, C₁-C₈alkyl, O, —OH, —CH₂CN, C₃-C₆alkenyl, C₇-C₉phenylalkyl unsubstituted or substituted on the phenyl by 1, 2 or 3 C₁-C₄alkyl; or C₁-C₈acyl; 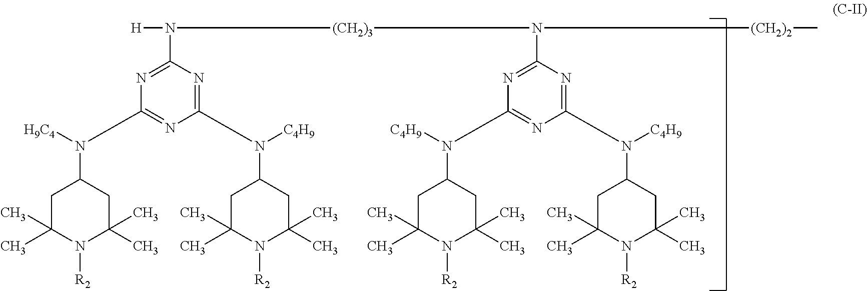
wherein the radicals R₂ have independently one of the meanings of R₁; 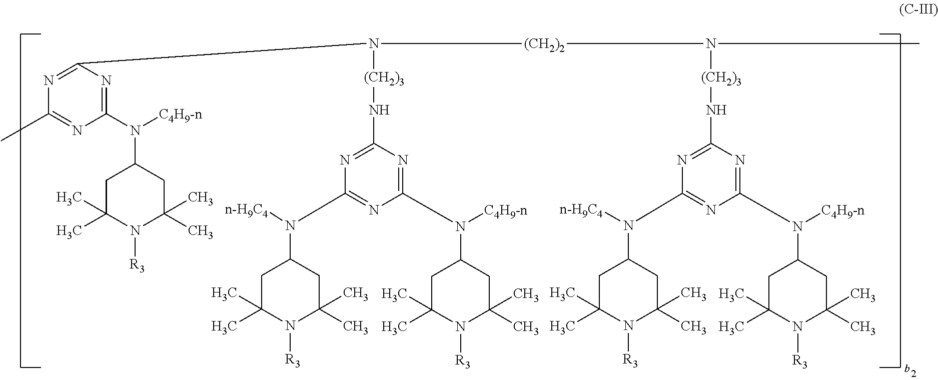
wherein b₂ is 2 to 20 and the radicals R₃ have independently one of the meanings of R₁; 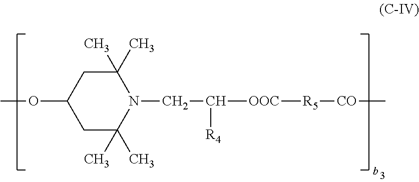
wherein R₄ is hydrogen or C₁-C₄alkyl,
R₅ is a direct bond or C₁-C₁₀alkylene, and
b₃ is a number from 2 to 20.

10. A photovoltaic module according to claim 1 wherein the layer or layers of component (2) contain the components (A), (B) and (C).

11. A photovoltaic module according to claim 1 wherein the layer or layers of component (2) contain one or more further components selected from the group consisting of
(D) a benzotriazole UV absorber,
(E) a phenolic antioxidant,
(F) a basic co-stabilizer and
(G) a neutralizer.

12. A photovoltaic module according to claim 7 wherein the layer or layers of component (2) contain the components (A), (B) and (C) wherein
component (A) is a synthetic polymer selected from a cyclic olefin polymer, a polycarbonate, a crosslinked ethylene vinyl acetate copolymer and a poly(methyl methacrylate);
component (B) is
a mixture of the compounds (B-I-a) and (B-II-a),
a mixture of the compounds (B-I-a) and (B-II-b) or
a mixture of the compounds (B-I-c) and (B-II-c); and
component (C) is a compound of formula (C-II-a)

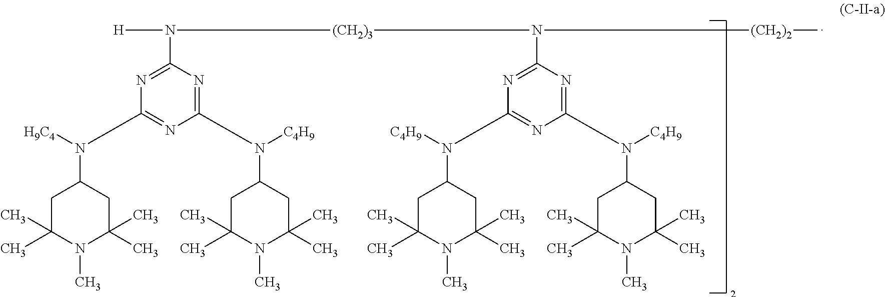

13. A photovoltaic module according to claim 1 wherein component (A) is a crosslinked ethylene vinyl acetate copolymer and component (B) is a mixture containing a compound of the formula (B-I) and a compound of the formula (B-II).

14. (canceled)

15. A photovoltaic module comprising
(1) a photovoltaic semiconductor and
(2) one or more layers containing
(A) a crosslinked ethylene vinyl acetate copolymer and
(B) a compound of formula (B-I-a) [chemical structure]
